(19) United States
(12) Patent Application Publication
(10) Pub. No.: US 2007/0228455 A1
(43) Pub. Date: Oct. 4, 2007

(54) SEMICONDUCTOR DEVICE AND MANUFACTURING METHOD THEREOF

(76) Inventors: Yoshitaka Sasago, Tachikawa (JP); Tomoyuki Ishii, Kokubunji (JP); Toshiyuki Mine, Fussa (JP)

Correspondence Address: MILES & STOCKBRIDGE PC, 1751 PINNACLE DRIVE, SUITE 500, MCLEAN, VA, 22102-3833, US

(21) Appl. No.: 11/619,561

(22) Filed: Jan. 3, 2007

(30) Foreign Application Priority Data
Mar. 31, 2006 (JP) JP2006-099540

(51) Int. Cl. H01L 27/115; H01L 21/8247

(52) U.S. Cl. 257/321; 438/264; 257/E27.103; 257/E29.304; 257/E21.549; 257/E21.681

(57) ABSTRACT

In the memory array area of a semiconductor substrate, memory cells of a NAND flash memory are arranged in a matrix in the row direction and the column direction. A plurality of memory cells arranged in the row direction are mutually isolated by device isolation trenches having a thin strip planar shape extending in the column direction. The diameter of the device isolation trenches in the row direction at the bottom portion thereof is larger than that near the surface.

### CROSS-REFERENCE TO RELATED APPLICATION

The present application claims priority from Japanese Patent Application No. JP 2006-099540 filed on Mar. 31, 2006, the content of which is hereby incorporated by reference into this application.

### TECHNICAL FIELD OF THE INVENTION

The present invention relates to a semiconductor device and a manufacturing method thereof. More specifically, it relates to a miniaturization technology for a semiconductor device having electrically programmable memory cells.

### BACKGROUND OF THE INVENTION

Of the electrically programmable nonvolatile memories, a so-called flash memory is known as a nonvolatile memory in which bulk erasing of data can be executed. The flash memory has excellent portability and impact resistance and can perform the electrical bulk erasing of data. Accordingly, the demand of the flash memory as a memory device for compact digital assistants such as a portable PC and a digital still camera has been rapidly increasing in recent years. For the expansion of the market thereof, the reduction in bit costs by the reduction of the memory cell area is the important factor, and various memory cell methods have been proposed for its achievement.

For example, International Electron Devices Meeting, 2003, pp. 823-826 (Non Patent Document 1) reports a structure in which, in an AND cell array which is one of contactless type cells suitable for large capacity, a third gate is provided in a memory cell in addition to a floating gate and a control gate, and an inversion layer which is formed on a surface of an underlying semiconductor substrate by the voltage applied to the third gate is used as a local bit line.

Further, in International Electron Devices Meeting, 2004, pp. 873-876, International Solid-State Circuits Conference, 2005, pp. 44-45 and p. 584, International Solid-State Circuits Conference, 2005, pp. 46-47 (Non Patent Documents 2, 3 and 4), examples of a so-called NAND flash memory which is one of contactless type cells suitable for large capacity are reported. By employing these structures, the physical area of a memory cell can be successfully reduced to nearly 4F² (F: minimum feature size), and a large capacity can be realized.

However, in the future, in order to further miniaturize the flash memory to 40 nm generation or further, it is necessary to maintain device isolation characteristics. Although it is not the technology of the flash memory, as a technology for improving the device isolation characteristics of a semiconductor device, the technology described in Japanese Patent Application Laid-Open Publication No. 8-70112 (Patent Document 1) is known. In this technology, the lateral dimensions of device isolation trenches are expanded in a silicon substrate which is lower in height than the silicon substrate surface, and the trenches are connected in the subsequent oxidization process, thereby shutting a leakage current bypass.

### SUMMARY OF THE INVENTION

However, if oxidization of a silicon substrate where trenches are connected as in the Patent Document 1 is performed for such miniaturized device isolation trenches as in the NAND flash memory, failures occur in the silicon substrate due to the stress caused by the volume expansion at the time when silicon is oxidized into a silicon oxide, and punch through occurs between source and drain in a memory transistor.

In a flash memory of a NAND array structure, device isolation trenches are disposed between a plurality of memory cells arranged in word line direction. Accordingly, when preferable device isolation characteristics cannot be acquired between the channels below memory cells isolated by the device isolation trenches, miss-read and miss-programming occur and the operation reliability is reduced.

The larger the depth and the width of device isolation trenches, the better the device isolation characteristics become. Therefore, when the width of the device isolation trench is reduced as a result of the reduction of memory cell size, the device isolation characteristics are deteriorated even with the same depth. Accordingly, if the memory cell size is to be reduced while maintaining the device isolation characteristics, it is necessary to increase the depth by the amount corresponding to the reduction in width. However, the processing of the trenches itself becomes difficult due to the increase of the aspect ratio of the trench. More specifically, with respect to the depth of the device isolation trench, the decrease of the processing yield as a result of the increase of the aspect ratio and the reduction of the device isolation characteristics are in a trade-off relation. Therefore, the reduction of memory cell size comes to a deadlock unless this problem can be solved.

Further, in addition to the device isolation characteristics, the reduction of miss-programming to the cells to which programming is not performed under a selected word line at the time of programming operation is the important subject in the NAND flash memory. The programming in the NAND flash memory is performed by the use of Fowler-Nordheim tunnel current via a tunnel insulator film. FIG. 8 is a circuit diagram for describing the voltage conditions at the time of programming operation. The programming is performed to a memory cell connected to a selected word line (SWL). The programming is performed to some memory cells and not performed to other memory cells depending on cases even though they are connected to the same SWL, and this is controlled by the voltage of a bit line. About 2V is applied to a select transistor (ST₁), 0V is applied to the bit line connected to the memory cell to which programming is performed under the selected word line (SWL), and about 3V is applied to the bit line connected to the memory cell to which programming is not performed. A common source line, a select transistor (ST₂), and a well are set to 0V, respectively. In this state, the voltage of unselected word line (USWL) is rapidly increased from 0V to about 10V (in about several micro seconds or less). Then, the voltage of a floating gate under the unselected word line (USWL) increases, and by the influence of the voltage, the voltage of a substrate surface under the memory cell will increase.

In the bit line whose bit line voltage is set to about 3V, since the select transistor (ST₁) is in an OFF state, the voltage of substrate surface under the memory cell increases to VH. On the other hand, in the bit line whose bit line voltage is set to 0V, since the select transistor (ST₁) is in an ON state, electrons are supplied from the bit line contact side to the substrate surface under the memory cell, and the voltage becomes 0V.

The determination method of the voltage VH of the substrate surface under the memory cell in the case where the programming is not performed is shown in FIG. 10. By rapidly increasing the voltage of the unselected word line (USWL) from 0V to 10V, the floating gate voltage also increases by ΔVfg. The voltage VH of the substrate surface is expressed by the product of the coupling ratio Cox/(Cox+Cdep) determined by the tunnel insulator film capacitance Cox and the depletion layer capacitance Cdep and ΔVfg.

VH=ΔVfg×Cox/(Cox+Cdep) (1)

By acquiring VH as large as possible, it is possible to prevent the miss-programming to the cell to which the programming is not performed. However, for this purpose, as is apparent from the equation (1), it is needed to increase Cox/(Cox+Cdep).

Accordingly, an object of the present invention is to provide a technology for realizing good device isolation characteristics and to increase the programming device voltage without increasing the depth of device isolation trenches disposed between memory cells in a miniaturized NAND flash memory.

The above and other objects and novel characteristics of the present invention will be apparent from the description of this specification and the accompanying drawings.

The typical ones of the inventions disclosed in this application will be briefly described as follows.

A semiconductor device according to the present invention comprises: a plurality of memory cells arranged in a matrix in a first direction and a second direction perpendicular thereto on a main surface of a semiconductor substrate of a first conductive type, wherein each of the plurality of memory cells is provided with a floating gate formed on the main surface of the semiconductor substrate via a gate insulator film and a control gate formed on the floating gate via an insulator film, the respective control gates of the plurality of memory cells arranged in the first direction form word lines extending in the first direction in a unified manner, the plurality of memory cells arranged in the second direction are connected in series, the memory cells adjacent in the first direction are mutually isolated by device isolation trenches formed in the main surface of the semiconductor substrate and extending in the second direction, and a diameter of the device isolation trench in the first direction at the bottom portion thereof is larger than a diameter thereof in the first direction at the surface of the semiconductor substrate.

The effects obtained by typical aspects of the present invention will be briefly described below.

It is possible to realize good device isolation characteristics in a miniaturized NAND flash memory.

### BRIEF DESCRIPTIONS OF THE DRAWINGS

FIG. 1 is a plan view showing a principal part of a semiconductor device according to a first embodiment of this invention;

FIG. 2 is a cross sectional view taken along the A-A line in FIG. 1;

FIG. 3 is a cross sectional view taken along the B-B line in FIG. 1;

FIG. 4 is a cross sectional view taken along the C-C line in FIG. 1;

FIG. 5 is a cross sectional view taken along the D-D line in FIG. 1;

FIG. 6 is a cross sectional view taken along the E-E line in FIG. 1;

FIG. 7 is a circuit diagram for describing the reading operation of the semiconductor device according to a first embodiment of this invention;

FIG. 8 is a circuit diagram for describing the programming operation of the semiconductor device according to a first embodiment of this invention;

FIG. 9A is a diagram for describing transmission of electrons between a substrate surface under the memory cell and the diffusion layer on the bit line contact side at the time of programming operation;

FIG. 9B is a diagram for describing transmission of electrons between a substrate surface under the memory cell and the diffusion layer on the bit line contact side at the time of programming operation;

FIG. 10 is a diagram for describing the relation of the voltage of a substrate surface under memory cell, the floating gate voltage change, the tunnel oxide film capacitance, and the substrate depletion layer capacitance in the case where the programming is not performed;

FIG. 11 is a diagram showing the path of current flowing between adjacent bit lines at the time of programming operation;

FIG. 12 is a circuit diagram for describing the erasing operation of the semiconductor device according to a first embodiment of this invention;

FIG. 13 is a cross sectional view showing a principal part of a manufacturing method of the semiconductor device according to a first embodiment of this invention;

FIG. 14 is a cross sectional view showing a principal part of the manufacturing method of the semiconductor device subsequent to FIG. 13;

FIG. 15 is a cross sectional view showing a principal part of the manufacturing method of the semiconductor device subsequent to FIG. 14;

FIG. 16 is a plan view showing a principal part of the manufacturing method of the semiconductor device subsequent to FIG. 15;

FIG. 17 is a cross sectional view showing a principal part of the manufacturing method of the semiconductor device subsequent to FIG. 16;

FIG. 18 is a cross sectional view showing a principal part of the manufacturing method of the semiconductor device subsequent to FIG. 17;

FIG. 19 is a cross sectional view showing a principal part of the manufacturing method of the semiconductor device subsequent to FIG. 18;

FIG. 20 is a cross sectional view showing a principal part of the manufacturing method of the semiconductor device subsequent to FIG. 19;

FIG. 21 is a cross sectional view showing a principal part of the manufacturing method of the semiconductor device subsequent to FIG. 20;

FIG. 22 is a cross sectional view showing a principal part of the manufacturing method of the semiconductor device subsequent to FIG. 21;

FIG. 23 is a cross sectional view showing a principal part of the manufacturing method of the semiconductor device subsequent to FIG. 22;

FIG. 24 is a cross sectional view showing a principal part of the manufacturing method of the semiconductor device subsequent to FIG. 23;

FIG. 25 is a cross sectional view showing a principal part of the manufacturing method of the semiconductor device subsequent to FIG. 24;

FIG. 26 is a cross sectional view showing a principal part of the manufacturing method of the semiconductor device subsequent to FIG. 25;

FIG. 27 is a cross sectional view showing a principal part of the manufacturing method of the semiconductor device subsequent to FIG. 26;

FIG. 28 is a cross sectional view showing a principal part of the manufacturing method of the semiconductor device subsequent to FIG. 27;

FIG. 29 is a cross sectional view showing a principal part of the manufacturing method of the semiconductor device subsequent to FIG. 29;

FIG. 30 is a cross sectional view showing a principal part of the manufacturing method of the semiconductor device subsequent to FIG. 29;

FIG. 31 is a cross sectional view showing a principal part of the manufacturing method of the semiconductor device subsequent to FIG. 30;

FIG. 32 is a cross sectional view showing a principal part of the manufacturing method of the semiconductor device subsequent to FIG. 31;

FIG. 33 is a cross sectional view showing a principal part of the manufacturing method of the semiconductor device subsequent to FIG. 32;

FIG. 34 is a cross sectional view showing a principal part of the manufacturing method of the semiconductor device subsequent to FIG. 33;

FIG. 35 is a cross sectional view showing a principal part of the manufacturing method of the semiconductor device subsequent to FIG. 34;

FIG. 36 is a cross sectional view showing a principal part of the manufacturing method of the semiconductor device subsequent to FIG. 35;

FIG. 37 is a cross sectional view showing a principal part of the manufacturing method of the semiconductor device subsequent to FIG. 36;

FIG. 38 is a cross sectional view showing a principal part of the manufacturing method of the semiconductor device subsequent to FIG. 37;

FIG. 39A is a graph showing the device isolation characteristics of the semiconductor devices in a first embodiment and a comparative example;

FIG. 39B is a diagram for describing the substrate depletion layer capacitance in the semiconductor device in a comparative example;

FIG. 39C is a diagram for describing the substrate depletion layer capacitance in the semiconductor device according to a first embodiment;

FIG. 40 is a cross sectional view showing a principal part of a semiconductor device according to a second embodiment of this invention;

FIG. 41 is a cross sectional view showing a principal part of a semiconductor device according to a second embodiment of this invention;

FIG. 42 is a cross sectional view showing a principal part of a semiconductor device according to a second embodiment of this invention;

FIG. 43 is a cross sectional view showing a principal part of a semiconductor device according to a second embodiment of this invention;

FIG. 44 is a cross sectional view showing a principal part of a semiconductor device according to a second embodiment of this invention;

FIG. 45 is a cross sectional view showing a principal part of a manufacturing method of the semiconductor device according to a second embodiment of this invention;

FIG. 46 is a cross sectional view showing a manufacturing method of the semiconductor device subsequent to FIG. 45;

FIG. 47 is a cross sectional view showing a principal part of a semiconductor device according to a third embodiment of this invention;

FIG. 48 is a cross sectional view showing a principal part of a semiconductor device according to a third embodiment of this invention;

FIG. 49 is a cross sectional view showing a principal part of a semiconductor device according to a third embodiment of this invention;

FIG. 50 is a cross sectional view showing a principal part of a semiconductor device according to a third embodiment of this invention;

FIG. 51 is a cross sectional view showing a principal part of a semiconductor device according to a third embodiment of this invention;

FIG. 52 is a cross sectional view showing a principal part of a manufacturing method of the semiconductor device according to a third embodiment of this invention;

FIG. 53 is a cross sectional view showing the manufacturing method of the semiconductor device subsequent to FIG. 52;

FIG. 54 is a cross sectional view showing the manufacturing method of the semiconductor device subsequent to FIG. 53;

FIG. 55 is a cross sectional view showing the manufacturing method of the semiconductor device subsequent to FIG. 54;

FIG. 56 is a cross sectional view showing the manufacturing method of the semiconductor device subsequent to FIG. 55;

FIG. 57 is a cross sectional view showing the manufacturing method of the semiconductor device subsequent to FIG. 56;

FIG. 58 is a cross sectional view showing the manufacturing method of the semiconductor device subsequent to FIG. 57;

FIG. 59 is a cross sectional view showing the manufacturing method of the semiconductor device subsequent to FIG. 58;

FIG. 60 is a cross sectional view showing the manufacturing method of the semiconductor device subsequent to FIG. 59;

FIG. 61 is a cross sectional view showing the manufacturing method of the semiconductor device subsequent to FIG. 60;

FIG. 62 is a cross sectional view showing the manufacturing method of the semiconductor device subsequent to FIG. 61;

FIG. 63 is a cross sectional view showing the manufacturing method of the semiconductor device subsequent to FIG. 62;

FIG. 64 is a cross sectional view showing the manufacturing method of the semiconductor device subsequent to FIG. 63;

FIG. 65 is a cross sectional view showing the manufacturing method of the semiconductor device subsequent to FIG. 64;

FIG. 66 is a cross sectional view showing the manufacturing method of the semiconductor device subsequent to FIG. 65;

FIG. 67 is a cross sectional view showing the manufacturing method of the semiconductor device subsequent to FIG. 66;

FIG. 68 is a cross sectional view showing a principal part of a semiconductor device according to a fourth embodiment of this invention;

FIG. 69 is a cross sectional view showing a principal part of a semiconductor device according to a fourth embodiment of this invention;

FIG. 70 is a cross sectional view showing a principal part of a semiconductor device according to a fourth embodiment of this invention;

FIG. 71 is a cross sectional view showing a principal part of a semiconductor device according to a fourth embodiment of this invention;

FIG. 72 is a cross sectional view showing a principal part of a semiconductor device according to a fourth embodiment of this invention;

FIG. 73 is a cross sectional view showing a principal part of a manufacturing method of the semiconductor device according to a fourth embodiment of this invention;

FIG. 74 is a cross sectional view showing the manufacturing method of the semiconductor device subsequent to FIG. 73;

FIG. 75 is a cross sectional view showing a principal part of a semiconductor device according to a fifth embodiment of this invention;

FIG. 76 is a cross sectional view showing a principal part of a semiconductor device according to a fifth embodiment of this invention;

FIG. 77 is a cross sectional view showing a principal part of a semiconductor device according to a fifth embodiment of this invention;

FIG. 78 is a cross sectional view showing a principal part of a semiconductor device according to a fifth embodiment of this invention;

FIG. 79 is a cross sectional view showing a principal part of a manufacturing method of the semiconductor device according to a fifth embodiment of this invention;

FIG. 80 is a cross sectional view showing a principal part of a semiconductor device according to a sixth embodiment of this invention;

FIG. 81 is a cross sectional view showing a principal part of a semiconductor device according to a sixth embodiment of this invention;

FIG. 82 is a cross sectional view showing a principal part of a semiconductor device according to a sixth embodiment of this invention;

FIG. 83 is a cross sectional view showing a principal part of a semiconductor device according to a sixth embodiment of this invention;

FIG. 84 is a cross sectional view showing a principal part of a semiconductor device according to a sixth embodiment of this invention;

FIG. 85 is a cross sectional view showing a principal part of a manufacturing method of the semiconductor device according to a sixth embodiment of this invention;

FIG. 86 is a cross sectional view showing a principal part of a semiconductor device according to a seventh embodiment of this invention;

FIG. 87 is a cross sectional view showing a principal part of a semiconductor device according to a seventh embodiment of this invention;

FIG. 88 is a plan view showing a principal part of the memory array area of a semiconductor device according to an eighth embodiment of this invention;

FIG. 89 is a cross sectional view showing a principal part of a semiconductor device according to an eighth embodiment of this invention;

FIG. 90 is a cross sectional view showing a principal part of a semiconductor device according to an eighth embodiment of this invention;

FIG. 91 is a cross sectional view showing a principal part of a semiconductor device according to an eighth embodiment of this invention;

FIG. 92 is a cross sectional view showing a principal part of a semiconductor device according to an eighth embodiment of this invention;

FIG. 93 is a cross sectional view showing a principal part of a semiconductor device according to an eighth embodiment of this invention;

FIG. 94 is a cross sectional view showing a principal part of a semiconductor device according to an eighth embodiment of this invention;

FIG. 95 is a cross sectional view showing a principal part of a semiconductor device according to an eighth embodiment of this invention;

FIG. 96 is a cross sectional view showing a principal part of a semiconductor device according to an eighth embodiment of this invention;

FIG. 97 is a circuit diagram for describing the reading operation of the semiconductor device according to an eighth embodiment of this invention;

FIG. 98 is a circuit diagram for describing the programming operation of the semiconductor device according to an eighth embodiment of this invention;

FIG. 99 is a circuit diagram for describing the erasing operation of the semiconductor device according to an eighth embodiment of this invention;

FIG. 100A is a diagram showing the reading voltage conditions of the semiconductor device according to an eighth embodiment of this invention;

FIG. 100B is a diagram showing the programming voltage conditions of the semiconductor device according to an eighth embodiment of this invention;

FIG. 101 is a plan view showing a principal part of a manufacturing method of the semiconductor device according to an eighth embodiment of this invention; and

FIG. 102 is a cross sectional view showing a principal part of a manufacturing method of the semiconductor device according to an eighth embodiment of this invention.

### DESCRIPTIONS OF THE PREFERRED EMBODIMENTS

Hereinafter, embodiments of the present invention will be described in detail with reference to the accompanying drawings. Note that components having the same function are denoted by the same reference symbols throughout the drawings for describing the embodiment, and the repetitive description thereof will be omitted.

### First Embodiment

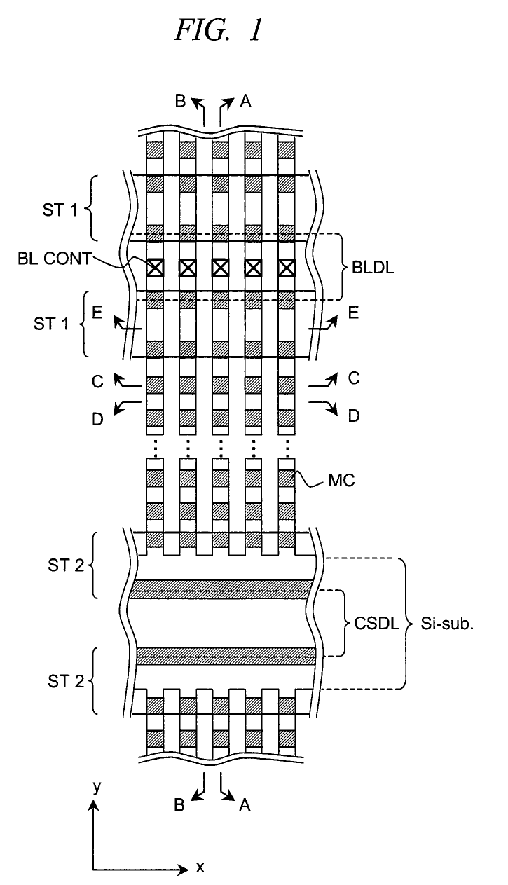

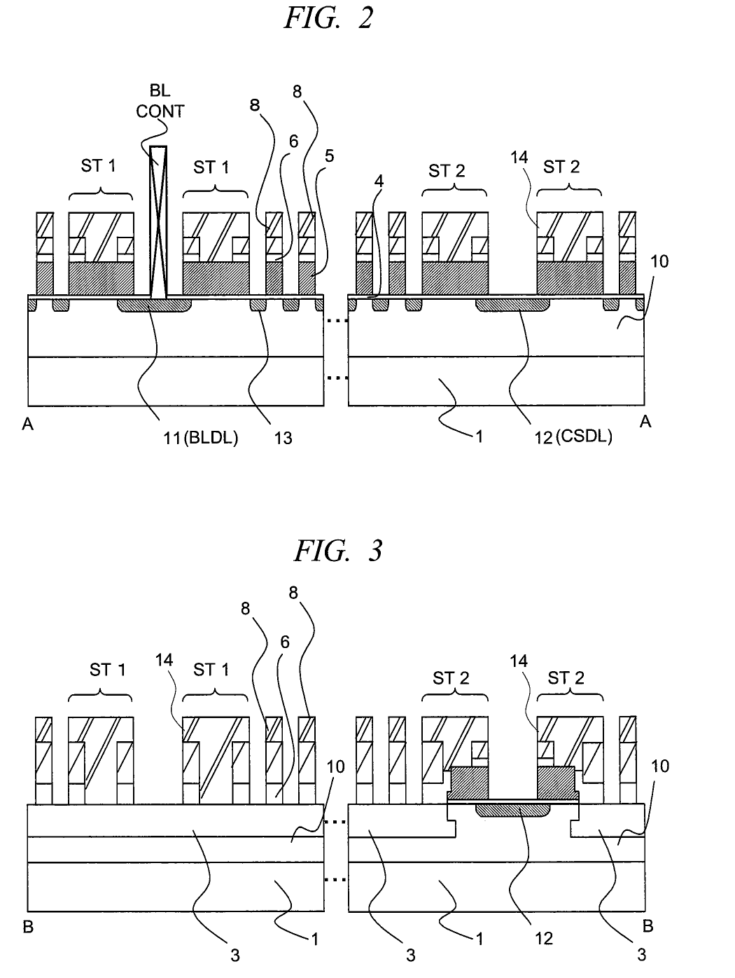

FIG. 1 is a plan view showing a principal part of a memory array area of a semiconductor device according to a first embodiment of the present invention. FIG. 2 to FIG. 6 are cross sectional views taken along A-A line, B-B line, C-C line, D-D line, and E-E line in FIG. 1, respectively. Note that illustration of some members is omitted in FIG. 1 for easy recognition of the structure of the memory array area.

The semiconductor device according to the present embodiment is a NAND flash memory. The memory cell is formed on a p type well 10 on the main surface of a semiconductor substrate (hereinafter referred to as substrate) 1 made of p type single crystal silicon, and it comprises a gate insulator film (tunnel insulator film) 4, a floating gate 5, an insulator film 6, a control gate 8, and an n type diffusion layers 13 (source, drain). The control gate 8 extends in the row direction (x direction in FIG. 1) and forms a word line WL. The p type well 10 and the floating gate 5 are isolated by the gate insulator film 4, and the floating gate 5 and the control gate 8 (word line WL) are isolated by the insulator film 6.

In the memory array area of the substrate 1, a plurality of memory cells with the above-mentioned structure are arranged in matrix in the row direction and the column direction (y direction in FIG. 1). A plurality of memory cells arranged in the row direction, that is, in the extending direction of the word line WL are isolated from each other by device isolation trenches 3 having a thin strip shape and extending in the column direction. On the other hand, a plurality of memory cells arranged in the column direction are connected in series via respective n type diffusion layers 13.

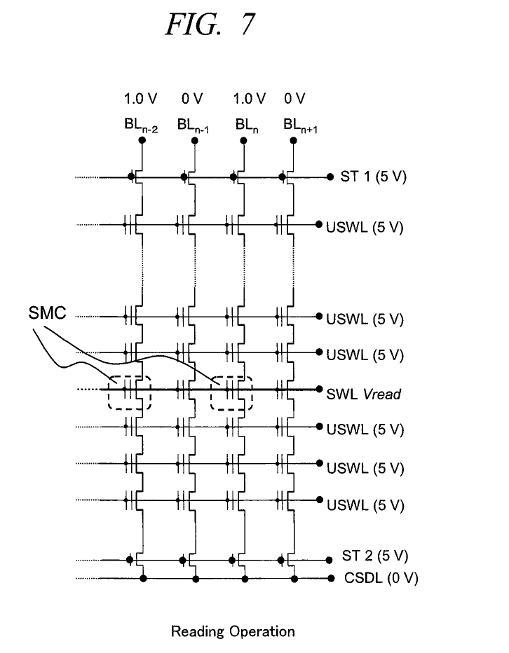

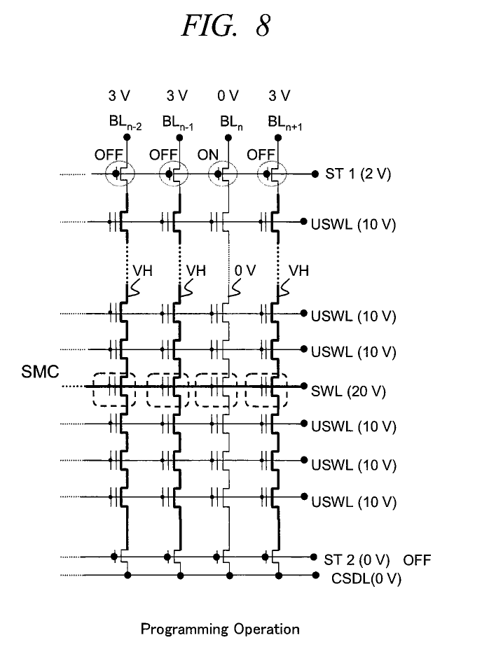

The memory cell row extending in the row direction is connected to a select transistor ST₁ at one end of the memory array area and is connected via an n type diffusion layer 11 (BLDL) of the select transistor ST₁ to a bit line contact (BLCONT). The bit line contact (BLCONT) is formed in an interlayer insulator film (not illustrated) of the upper layer of the word line WL and is connected to a bit line BL (FIG. 7, FIG. 8) made of metal wire formed on this interlayer insulator film. Further, the memory cell row extending in the column direction is connected to an n type diffusion layer 12 of the select transistor ST₂ at the other end of the memory array area. The n type diffusion layer 12 of the select transistor ST₂ forms a common source line (CSDL).

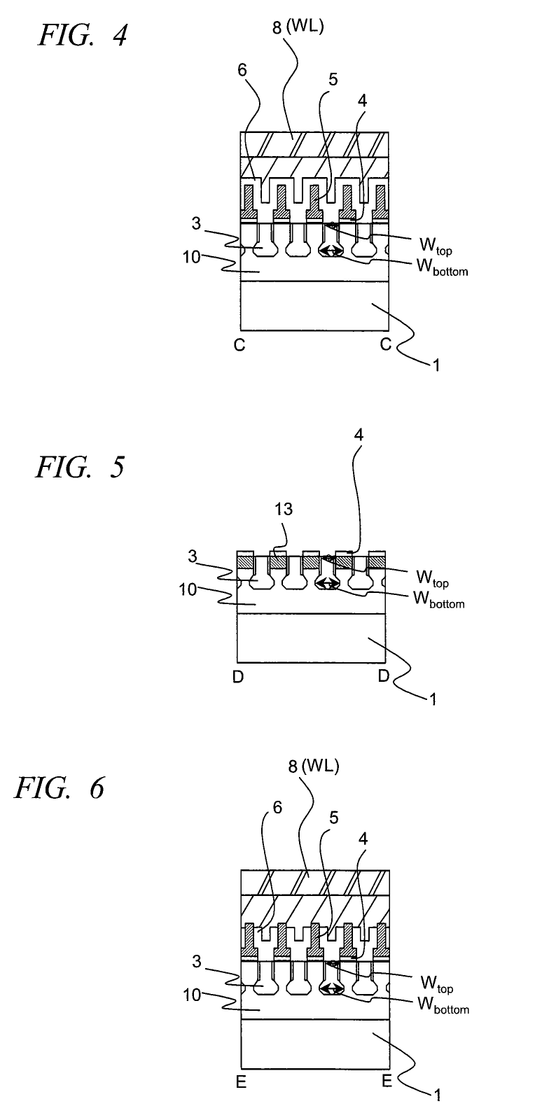

As shown in FIG. 4 and FIG. 5, the NAND flash memory according to the present embodiment is characterized by that the diameter (Wbottom) in the row direction at the bottom of the device isolation trench 3 is larger than the diameter (Wtop) in the row direction at the vicinity of the surface (Wbottom>Wtop). As is described later herein, by forming such a cross sectional shape of the device isolation trench 3, it is possible to achieve good device isolation characteristics even when the depth of the trench is reduced.

Next, the operation of the NAND flash memory will be described below. First, at the time of reading operation, as shown in FIG. 7, 1V is applied to the bit lines (BLₙ, BLₙ₋₂) connected to the selected memory cell (SMC), about 5V is applied to the select transistors (ST₁, ST₂), about 5V is applied to unselected word line (USWL), 0V is applied to the common source line (CSDL), and 0V is applied to the p type well 10, respectively. Further, read determination voltage (Vread) is applied to the selected word line (SWL) to determine ON or OFF of the selected memory cell (SMC).

In the programming operation, Fowler-Nordheim tunnel current via the tunnel insulator film 4 is used, and the programming is performed to a plurality of memory cells connected to the selected word line (SWL). In this case, the distinction between the memory cells to which programming is to be performed and the memory cells to which programming is not to be performed among the plurality of memory cells connected to the selected word line (SWL) is controlled by the size of the voltage to be applied to the bit line (BL).

More specifically, at the time of programming operation, as shown in FIG. 8, about 2V is applied to the select transistor (ST₁), 0V is applied to the bit line (BLₙ) connected to the selected memory cell (SMC), and about 3V is applied to other bit lines, respectively. The common source line (CSL) and the select transistor (ST₂) are set to 0V. In this state, the voltage of the unselected word line (USWL) is increased rapidly (several micro seconds or less) from 0V to 10V. Then, the voltage of the floating gate (5) under the unselected word line (USWL) increases, and due to the influence thereof, the voltage of the substrate surface under the memory cell will increase. At this time, since the select transistor (ST₁) connected to the bit line to which the voltage about 3V is applied becomes OFF state, the voltage of the substrate surface under the memory cell increases (VH). On the other hand, since the select transistor (ST₁) connected to the bit line (BLₙ) to which 0V is applied becomes ON state, electrons are supplied from the bit line contact (BLCONT) side to the substrate surface under the memory cell, and the voltage thereof becomes 0V.

Next, the voltage of the selected word line (SWL) is increased from 0V to about 20V. At this time, in the bit line (BLₙ) where the voltage of the substrate surface is 0V, a large voltage difference occurs between the floating gate and the substrate surface, and electrons are injected by tunnel current from the surface of the substrate (1) to the floating gate (5), thereby performing the programming. On the other hand, in the bit line where the voltage of the substrate surface is VH, the voltage difference between the floating gate and the substrate surface is decreased, and the programming is not performed.

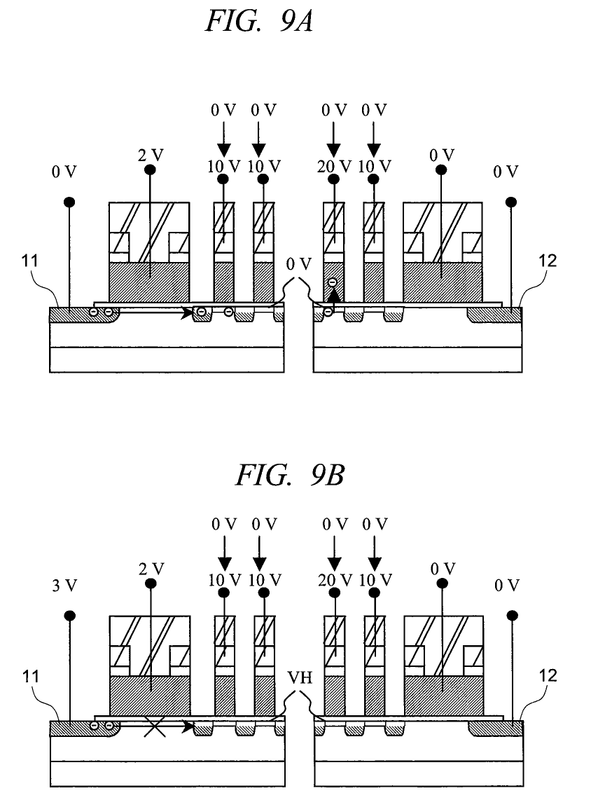

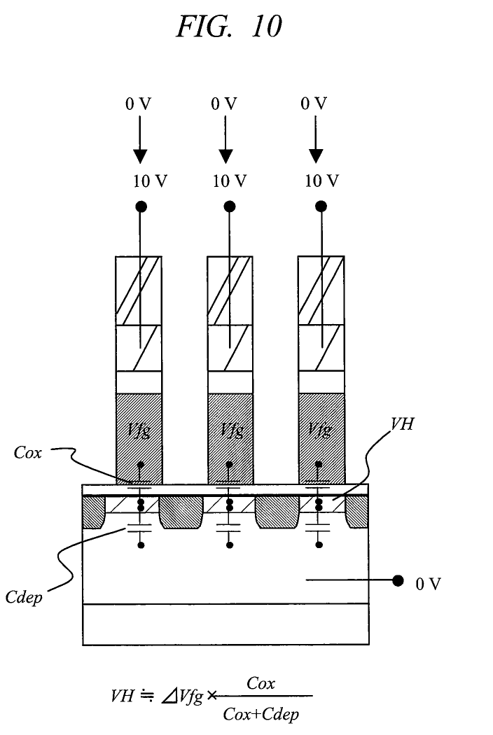

The transmission of electrons between the substrate surface under the memory cell and the diffusion layer 11 on the bit line contact (BLCONT) side via the select transistor (ST₁) is shown in FIG. 9A and FIG. 9B. The case where programming is performed is shown in FIG. 9A, and the case where programming is not performed is shown in FIG. 9B. Also, the relation of the substrate surface voltage under memory cell (VH), the floating gate voltage change (ΔVfg), the tunnel oxide film capacitance (Cox), and the substrate depletion layer capacitance (Cdep) in the case where programming is not performed is shown in FIG. 10.

When the unselected word line (USWL) is rapidly increased from 0V to 10V, the voltage of the floating gate also increases by ΔVfg. The substrate surface voltage VH is expressed by the product of the coupling ratio [Cox/(Cox+Cdep)] determined by the tunnel insulator film capacitance Cox, the depletion layer capacitance Cdep, and the floating gate voltage change (ΔVfg).

VH=ΔVfg×Cox/(Cox+Cdep) (1)

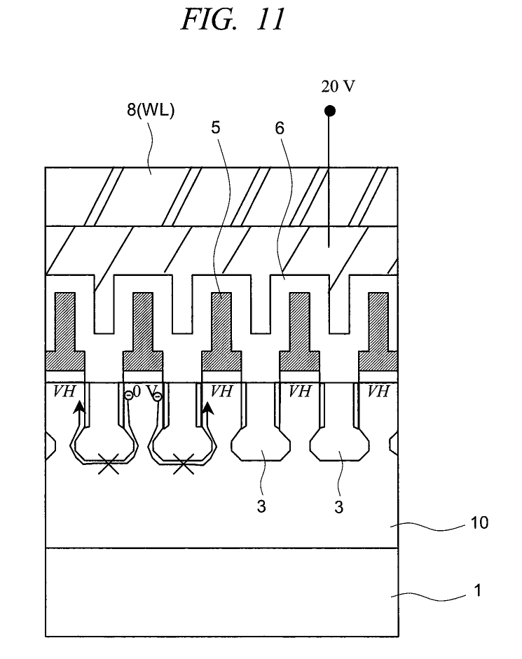

At the time of programming operation, there are some places where the bit line connected to the memory cell where programming is performed (substrate surface voltage=0V) and the bit line connected to the memory cell where programming is not performed (substrate surface voltage=VH) are adjacent to each other. At this time, if the insulation between substrate surfaces is insufficient, current flows between them as shown in FIG. 11, and the substrate surface voltage of the bit line connected to the memory cell where programming is not performed decreases below VH and the voltage of the bit connected to the memory cell where programming is performed increases over 0V. When this current is large, the difference between two voltages becomes small, and programming is not performed to the memory cell where programming is to be performed or programming is performed to the memory cell where programming is not to be performed. Accordingly, the programming failures occur.

In the present embodiment, the diameter at the bottom of the device isolation trench 3 is made larger than the diameter at the vicinity of the surface. By this means, even if the trench is shallow, since the path of current flowing along the wall surface of the trench becomes effectively long, it is possible to secure the insulation properties between substrate surfaces and also possible to obtain preferable device isolation characteristics.

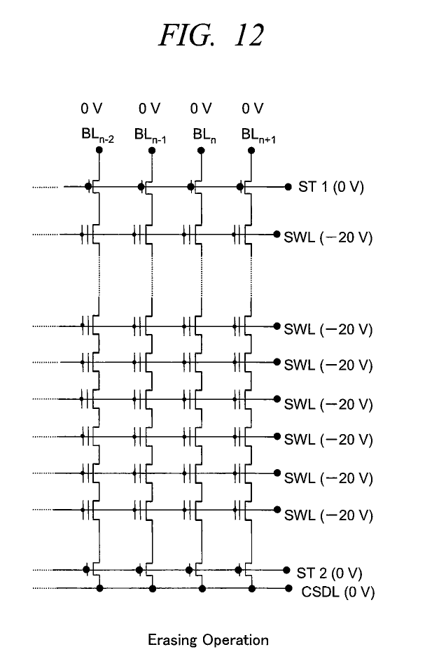

At the time of erasing operation, as shown in FIG. 12, voltage of about −20V is applied to all the word lines between the select transistors (ST₁, ST₂), and electrons are ejected from the floating gate to the substrate via the gate insulator film by the Fowler-Nordheim tunnel current.

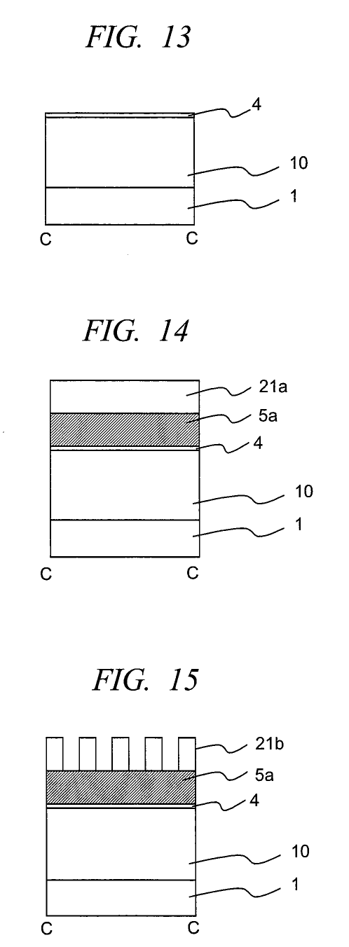

Next, the manufacturing method of the NAND flash memory will be described with reference to FIG. 13 to FIG. 38. Note that FIG. 13 to FIG. 15 and FIG. 17 to FIG. 30 correspond to the cross section views taken along C-C line in FIG. 1.

First, as shown in FIG. 13, phosphorus is ion-implanted into a substrate 1 made of p type single crystal silicon to form a p type well 10. Then, a gate insulator film 4 made of a silicon oxide of film with a thickness of about 9 nm is formed on the surface of the p type well 10 by the use of thermal oxidization method. Next, as shown in FIG. 14, a phosphorus doped polysilicon film 5a and a silicon nitride film 21a are deposited on the gate insulator film 4 by the CVD method. The polysilicon film 5a is a conductive film to be a floating gate (5) in the latter process and the film thickness thereof is, for example, about 50 nm to 100 nm. Further, the film thickness of the silicon nitride film 21a is, for example, about 50 nm.

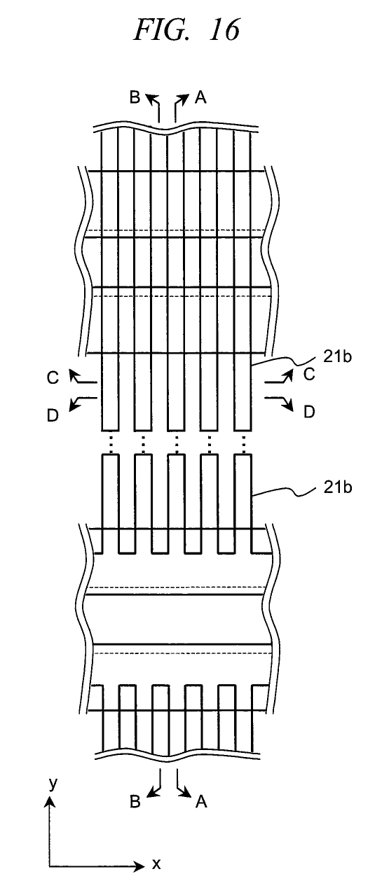

Next, as shown in FIG. 15, the silicon nitride film 21a is patterned by the dry etching with using a photoresist film as a mask, and a silicon nitride film 21b is formed. FIG. 16 shows the planar shape of the silicon nitride film 21b formed in the memory array area. The silicon nitride film 21b has a thin strip shape extending in the column direction (y direction), and it covers the portion to be the active area of the substrate 1.

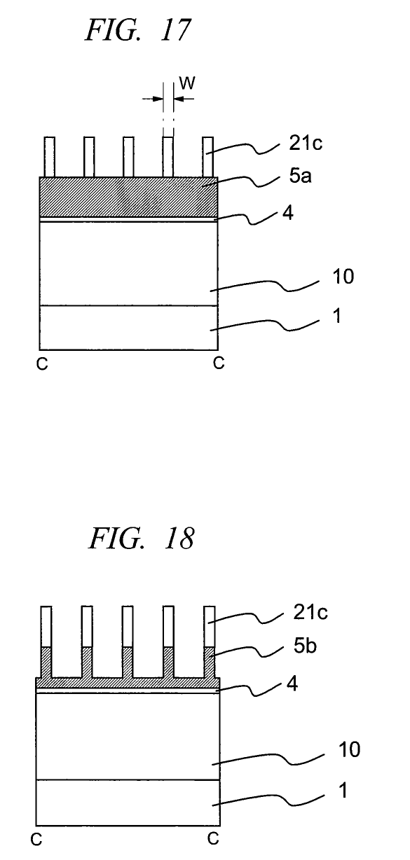

Next, as shown in FIG. 17, the silicon nitride film 21b is slimmed by the dry etching or wet etching to form a silicon nitride film 21c. The width (W) of the silicon nitride film 21c obtained by this slimming process is smaller than the minimum feature size of the photolithography. Next, as shown in FIG. 18, the polysilicon film 5a is patterned by the dry etching with using the silicon nitride film 21c as a mask. At this time, etching is stopped before the underlying gate insulator film 4 exposes, and a polysilicon film 5b with a pectinate cross sectional shape is formed.

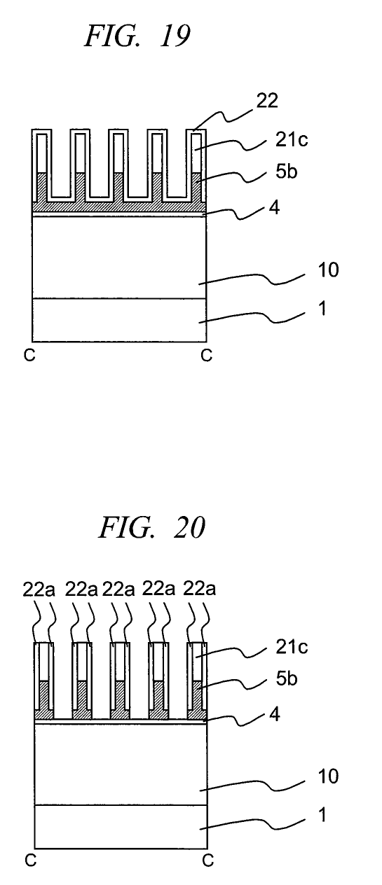

Next, as shown in FIG. 19, a silicon oxide film 22 is deposited by the use of CVD method. The silicon oxide film 22 is deposited to have a small film thickness so that it does not fill the concave portions of the polysilicon film 5b patterned into the pectinate shape. Next, as shown in FIG. 20, through the anisotropic dry etching of the silicon oxide film 22, sidewall-shaped silicon oxide films 22a are formed on the sidewalls of the polysilicon film 5b and the silicon nitride film 21c.

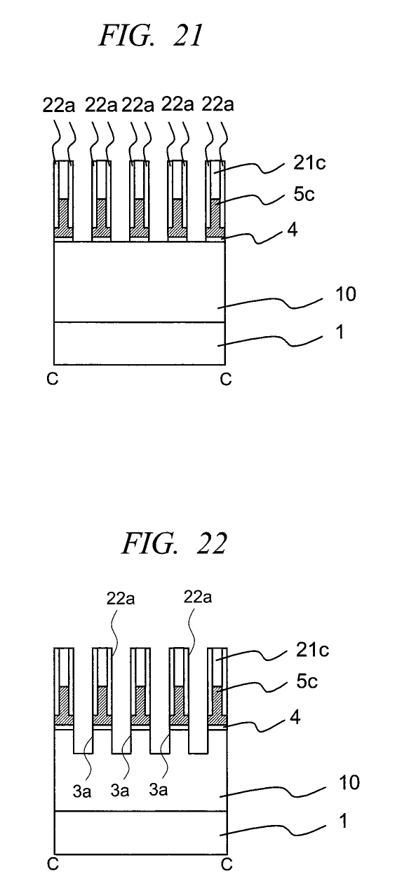

Next, as shown in FIG. 21, the polysilicon film 5b and the underlying gate insulator film 4 are dry etched with using the silicon nitride film 21c and the silicon oxide film 22a formed on the side surface thereof as masks, and a part of the surface of the p type well 10 is exposed. By this etching, the polysilicon films 5b become a plurality of polysilicon films 5c having a reversed T-shaped cross section and mutually isolated at a specified interval. Next, as shown in FIG. 22, the exposed p type well 10 is dry etched, thereby forming a plurality of trenches 3a. These trenches 3a have a thin strip planar shape extending in the column direction.

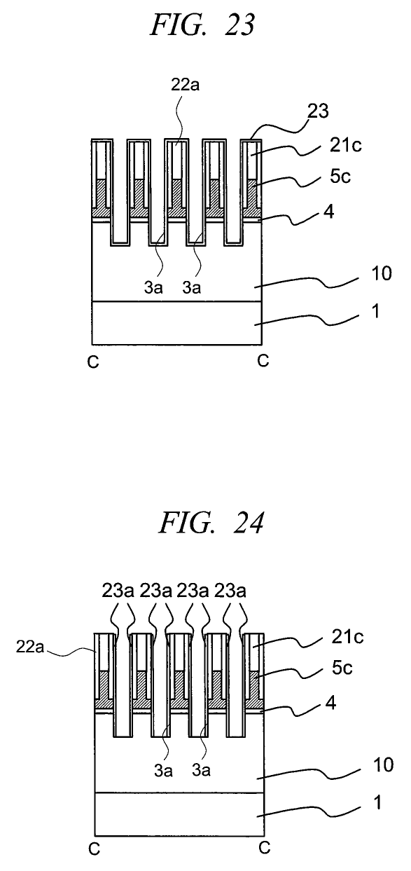

Next, as shown in FIG. 23, a silicon oxide film 23 is deposited by the use of CVD method. The silicon oxide film 23 is deposited to have a small film thickness so as not to completely fill the trenches 3a. Note that it is also possible to form a thermal oxide film (silicon oxide film) on the inner wall of the trenches 3a and the side surface of the polysilicon film 5b by the use of thermal oxidization method instead of the CVD method. Next, as shown in FIG. 24, by the anisotropic dry etching of the silicon oxide film 23, the p type well 10 at the bottom of the trenches 3a is exposed, and sidewall-shaped silicon oxide films 23a are formed on the side surfaces of the silicon oxide films 22a, the polysilicon films Sc and the trenches 3a.

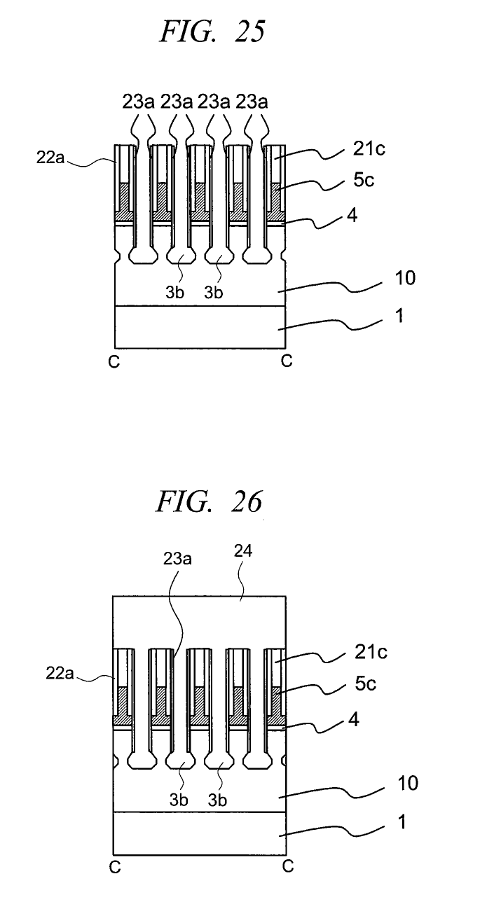

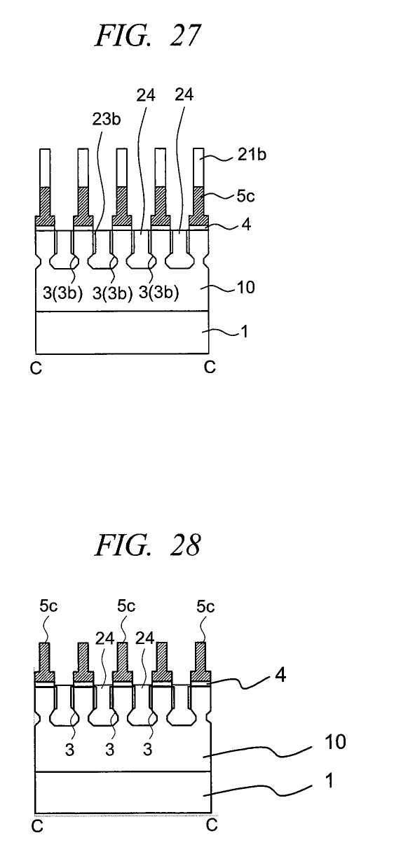

Next, as shown in FIG. 25, the isotropic dry etching of the p type well 10 exposed at the bottom of the trenches 3a is performed. This etching may be either dry or wet. By this means, the bottom portions of the trenches 3a are expanded in the vertical direction and the horizontal direction with respect to the main surface of the substrate 1, and trenches 3b where the diameter of the bottom portion is larger than the diameter at the vicinity of the opening portion are formed. Next, as shown in FIG. 26, a silicon oxide 24 is deposited by the use of CVD method to completely fill the trenches 3b with the silicon oxide 24. Thereafter, as shown in FIG. 27, the silicon oxide 24 outside the trenches 3b and sidewall-shaped silicon oxide films 22a and 23a are etched back, and the silicon oxide 24 is left only in the trenches 3b. Through the processes described above, the device isolation trenches 3 where the diameter (diameter in the row direction) at the bottom is larger than that at the vicinity of the surface as shown in FIG. 4 and FIG. 5 are completed.

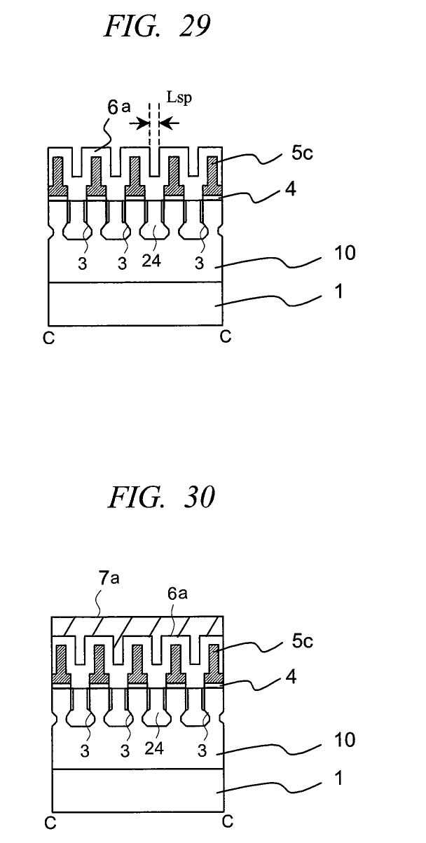

Subsequently, the silicon nitride film 21c at the top of the polysilicon film 5c is removed by the dry etching or wet etching as shown in FIG. 28. Next, as shown in FIG. 29, an insulator film 6a is deposited to have a small film thickness so as not to completely fill the spaces between adjacent polysilicon films 5c, and the surfaces of the polysilicon films 5c are covered with the insulator film 6a. The insulator film 6a is composed of, for example, a silicon oxide film deposited by the CVD method or a stacked film of a silicon oxide film/a silicon nitride film/a silicon oxide deposited by the CVD method.

At this time, if the spaces of the adjacent polysilicon films 5c are completely filled with the insulator film 6a, when the control gate (8) is formed on the insulator film 6 in latter process, the increase of capacitance between the control gate and the floating gate by the use of the sidewall of the floating gate (5) is not expected, and therefore, it becomes difficult to secure the coupling ratio. However, in the present embodiment, the cross sectional shape of the polysilicon film 5c is made into a reversed T shape. Therefore, even when the spaces between adjacent polysilicon films 5c become narrow due to the reduction of the memory cell size, the insulator film 6 can be deposited so as not to completely fill these spaces. In other words, since the space (Lsp) shown in FIG. 29 can be secured, it is possible to increase the capacitance between the control gate and the floating gate by the use of the sidewall of the floating gate (5) and also possible to secure the coupling ratio.

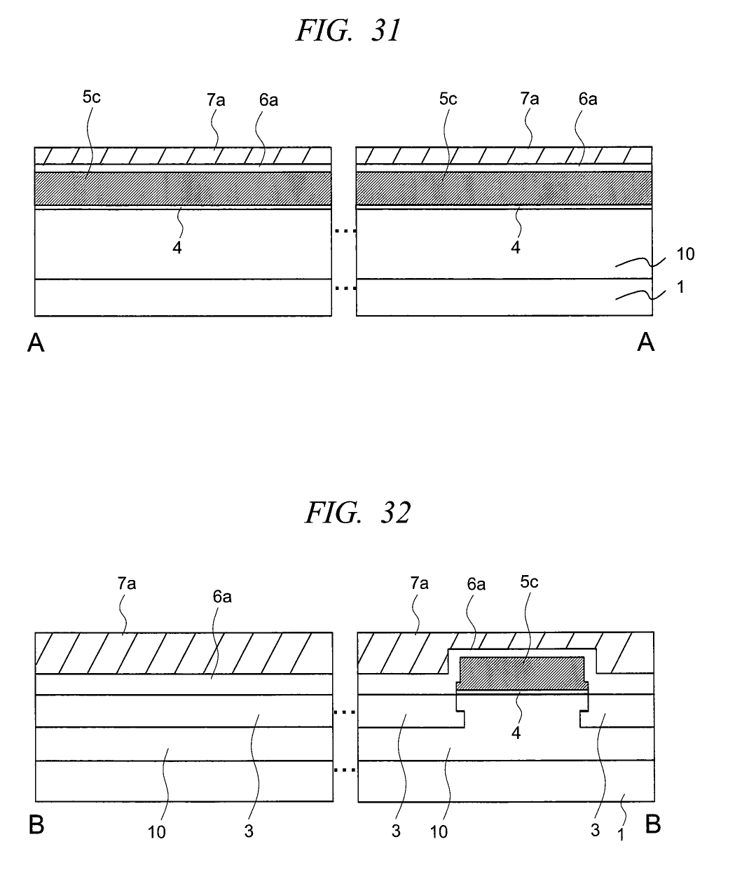

Next, as shown in FIG. 30, a phosphorus doped polysilicon film 7a is deposited on the insulator film 6a by the CVD method. The polysilicon film 7a is a conductive film to be a part of the control gate (7) formed in the latter process. FIG. 31 is a cross sectional view taken along A-A line in FIG. 1 at this time, and FIG. 32 is a cross sectional view taken along B-B line in FIG. 1 at this time. The subsequent processes will be described with reference to these cross sectional views taken along the A-A line and the B-B line.

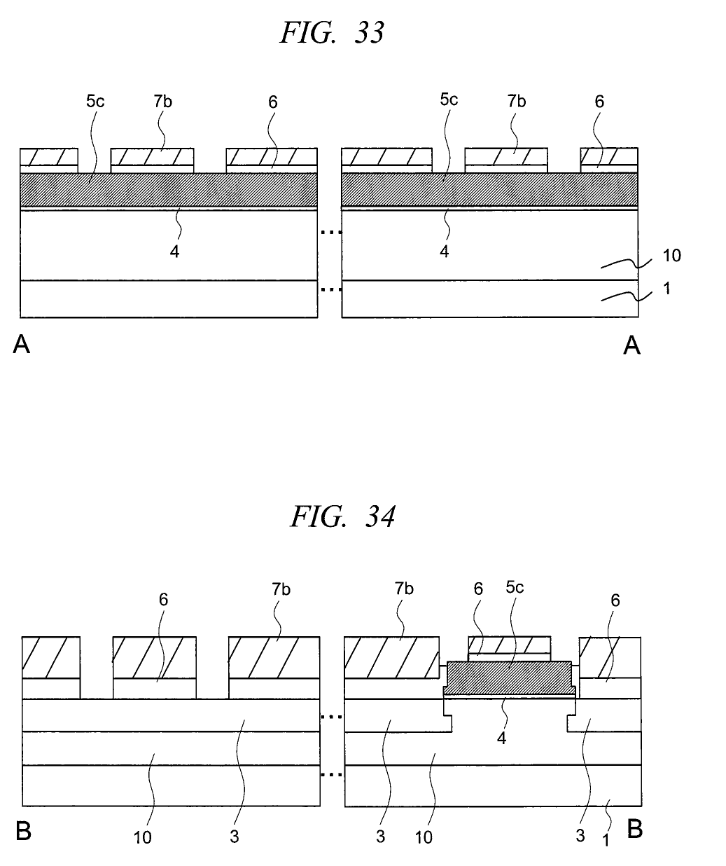

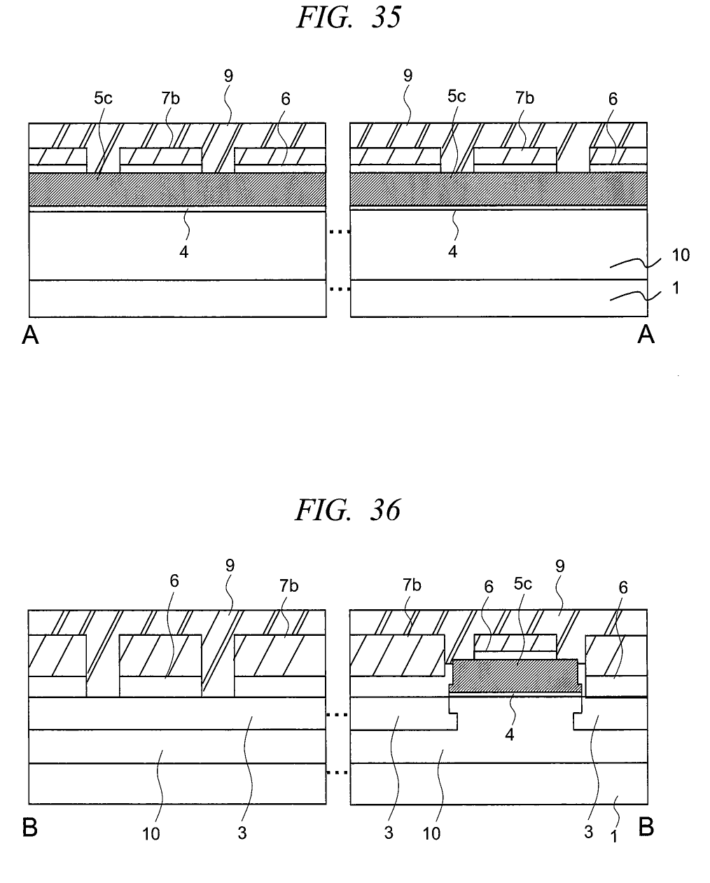

Next, as shown in FIG. 33 and FIG. 34, the polysilicon film 7a and the insulator film 6a in the area where the select transistors (ST₁, ST₂) are to be formed in the latter process are patterned to be a polysilicon film 7b and an insulator film 6, respectively. Next, as shown in FIG. 35 and FIG. 36, a metal film 9 is deposited by the use of sputtering method. The metal film 9 is composed of, for example, a stacked film of a tungsten nitride film and a tungsten film, a metal silicide film such as a tungsten silicide film and the like.

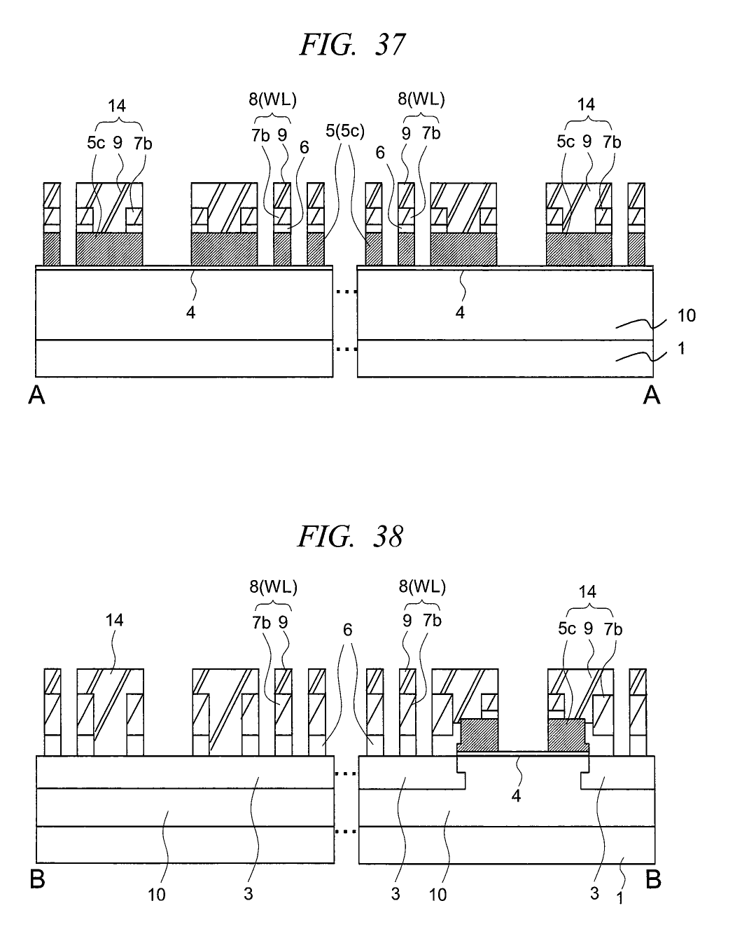

Next, as shown in FIG. 37 and FIG. 38, the metal film 9, the polysilicon film 7b, the insulator film 6, and the polysilicon film 5c are patterned sequentially by the dry etching with using a photoresist film as a mask. Through the processes described above, the control gate 8 (word line WL) made of the stacked film of the metal film 9 and the polysilicon film 7b and the floating gate 5 made of the polysilicon film 5c are formed. Further, at the end of the memory array area, the gate electrodes 14 of the select transistors (ST₁, ST₂) made of the stacked film of the metal film 9 and the polysilicon films 7b and 5c are formed.

Next, arsenic is ion implanted into the p type well 10 to form an n type diffusion layer (BLDL) 11, an n type diffusion layer (CSDL) 12 and an n type diffusion layer 13. By doing so, the memory cell and the select transistors (ST₁, ST₂) shown in FIG. 1 to FIG. 6 are completed. Although the illustration thereof is omitted, thereafter, an interlayer insulator film is formed on the control gate 8 (word line WL), the interlayer insulator film is etched to form contact holes which reach the word line WL, the p type well 10, the select transistors (ST₁, ST₂), the n type diffusion layer (BLDL) 11 and the n type diffusion layer (CSDL) 12, respectively, and a metal wire (bit line) is formed on the interlayer insulator film. By this means, the NAND flash memory according to the present embodiment is completed.

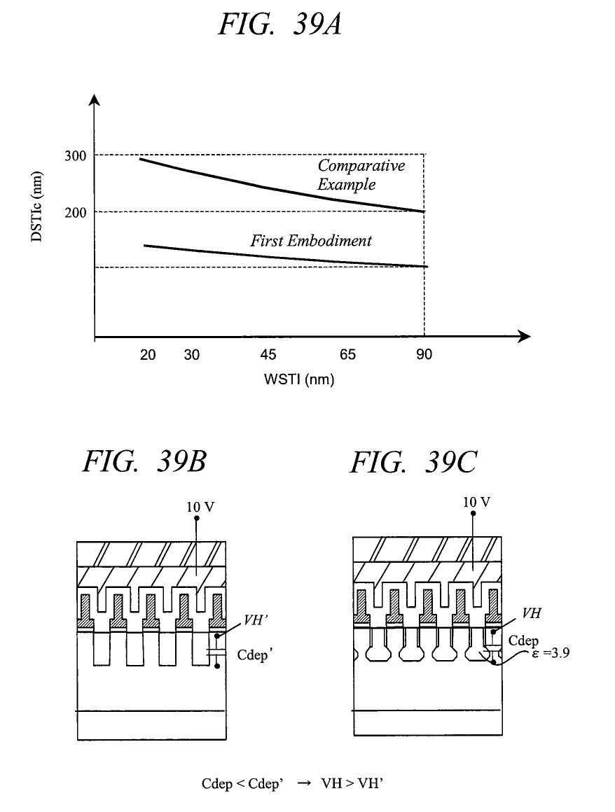

FIG. 39A is a graph for comparing the device isolation characteristics of a NAND flash memory where the diameter of the device isolation trench at the vicinity of the surface is almost the same as that at the bottom (comparative example) and the device isolation characteristics of the NAND flash memory according to the present embodiment. The horizontal axis of the graph represents the width (WSTI) of the device isolation trench, and the vertical axis thereof represents the minimum trench depth (DSTIc) for realizing the device isolation. As is apparent from the graph, in the NAND flash memory according to the present embodiment, even when the width of the device isolation trench is the same as that of the comparative example, the minimum trench depth for realizing the device isolation can be reduced. More specifically, according to the present embodiment, it is possible to reduce the memory cell size without increasing the aspect ratio of the device isolation trench, and consequently, it is possible to increase the capacity of a NAND flash memory without reducing the manufacturing yield.

Further, as shown in FIG. 39C, in the NAND flash memory according to the present embodiment, the diameter at the bottom of the device isolation trench is increased, and accordingly, the device isolation trench expands to the lower portion of the memory cell. On the other hand, as shown in FIG. 39B, in the comparative example, the device isolation trench does not extend to the lower portion of the memory cell. Since a silicon oxide film (relative dielectric constant=3.9) whose dielectric constant is lower than that of silicon constituting the substrate (relative dielectric constant=11.9) is embedded in the device isolation trench, when the device isolation trench extends to the lower portion of the memory cell, the substrate depletion layer capacitance (Cdep) is effectively decreased (Cdep<Cdep′). Accordingly, since the coupling ratio [Cox/(Cox+Cdep)] shown in the equation (1) increases, it is possible to generate the substrate surface voltage (VH) for realizing programming prevention with a lower floating gate voltage change (ΔVfg). That is, an effect that it is possible to reduce the voltage to be applied to the unselected word line at the time of programming operation can be obtained.

### Second Embodiment

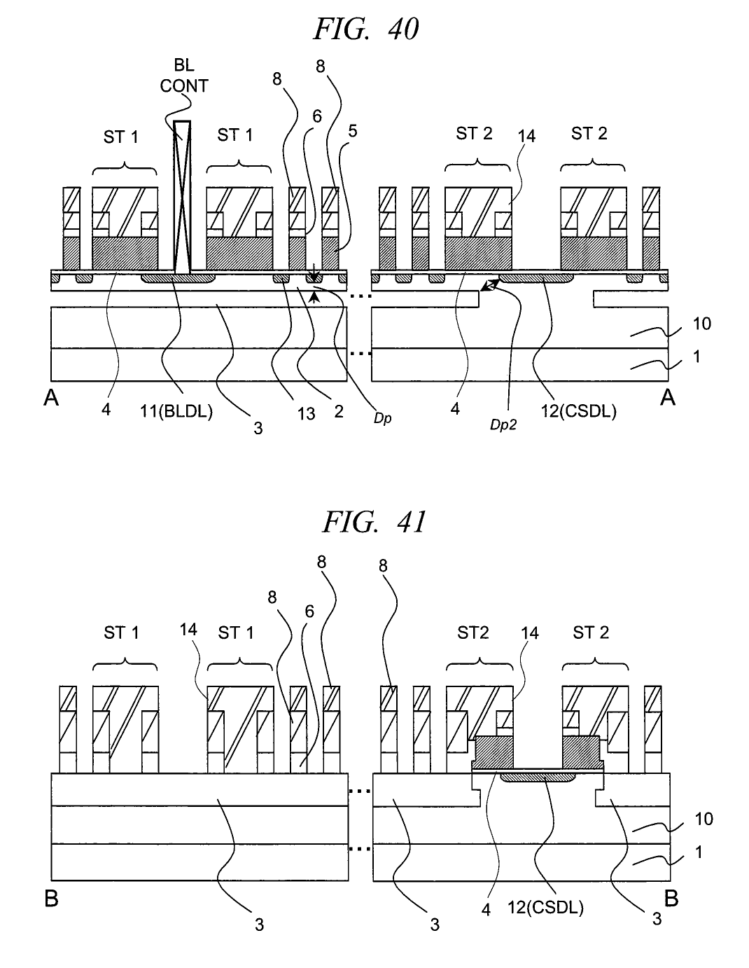

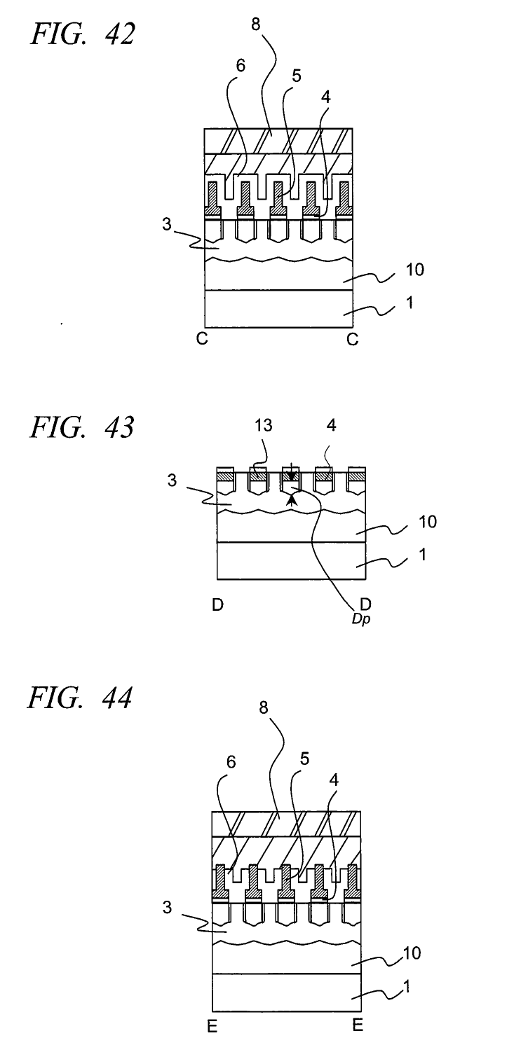

In the present embodiment, similar to the above-mentioned first embodiment, the diameter at the bottom of the device isolation trench is larger than that of the diameter at the vicinity of the surface. However, as shown in FIG. 40 to FIG. 44, in the present embodiment, the diameter at the bottom of the device isolation trench 3 is further expanded, and the bottom portion of the isolation trench 3 is connected to those of other device isolation trenches 3 of adjacent memory cells. More specifically, a plurality of device isolation trenches 3 extending in parallel in the column direction of the memory array area are mutually separated at the vicinity of the surfaces thereof, but they are mutually connected at the bottoms thereof. Note that FIG. 40 to FIG. 44 are cross sectional views taken along A-A line, B-B line, C-C line, D-D line, and E-E line in FIG. 1, respectively.

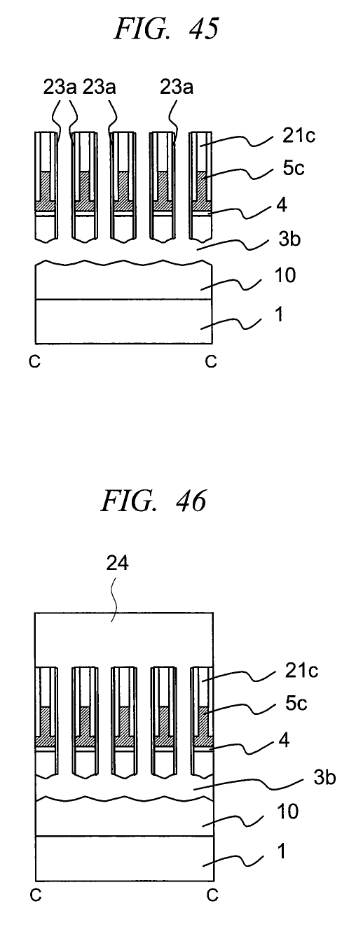

The manufacturing method of the NAND flash memory having the device isolation trench 3 as mentioned above will be described below. First, according to the processes shown in FIG. 13 to FIG. 25 in the first embodiment, after the trenches 3a are formed in the p type well 10, the p type well 10 exposed at the bottom portions of the trenches 3a is isotropically etched. By this means, the bottom portions of the trenches 3a are expanded in the vertical direction and the horizontal direction with respect to the main surface of the substrate 1, and the trenches 3b where the diameter at the bottom is larger than the diameter at the vicinity of the opening portion are formed. Subsequently, as shown in FIG. 45, the p type well 10 at the bottom of the trenches 3b is further isotropically etched, and the diameter at the bottom portions of the trenches 3b is further expanded, and the adjacent trenches 3b are connected at their bottoms portions. Next, as shown in FIG. 46, the silicon oxide 24 is deposited by the use of the CVD method to completely fill the trenches 3b with the silicon oxide 24. The subsequent processes are the same as those in the first embodiment.

In the case where the device isolation trench 3 is formed to have the structure mentioned above, it is preferable that the n type diffusion layers 13 (source, drain) of the memory cell do not reach the device isolation trench 3. In other words, it is preferable that the distance (Dp) from the bottom of the n type diffusion layer 13 to the device isolation trench 3 shown in FIG. 40 and FIG. 43 becomes a positive value (Dp>0). In the case where Dp>0, electrons ejected from the floating gate 5 to the substrate surface at the time of erasing operation are transmitted to the bulk silicon through the p type well 10 between the n type diffusion layer 13 and the device isolation trench 3. However, when Dp becomes 0, electrons ejected from the floating gate 5 are accumulated in the p type well 10 between the n type diffusion layer 13 and the device isolation trench 3, and accordingly, the voltage difference between the floating gate and the substrate surface is decreased, and the erasing speed becomes very slow. From the same reason, it is also preferable that the distance (Dp2) from the end of the n type diffusion layer 12 (common source line) to the device isolation trench 3 shown in FIG. 40 becomes a positive value (Dp2>0).

In the present embodiment, the device isolation characteristics are secured by the insulation of the silicon oxide film (24) embedded in the device isolation trench 3 instead of that of silicon. Accordingly, it is possible to realize further preferable device isolation characteristics in comparison with the first embodiment.

Further, in the present embodiment, the device isolation trenches 3 in which the silicon oxide film (relative dielectric constant=3.9) whose dielectric constant is lower than that of silicon (specific dielectric constant=11.9) is embedded expand over the entire memory array area. Accordingly, the substrate depletion layer capacitance (Cdep) in the equation (1) is further reduced than that in the first embodiment. Therefore, the coupling ratio [Cox/(Cox+Cdep)] is further increased. As a result, it is possible to generate the substrate surface voltage (VH) for realizing programming prevention with a further lower floating gate voltage change (ΔVfg) and possible to further decrease the voltage to be applied to unselected word lines at the time of programming operation.

### Third Embodiment

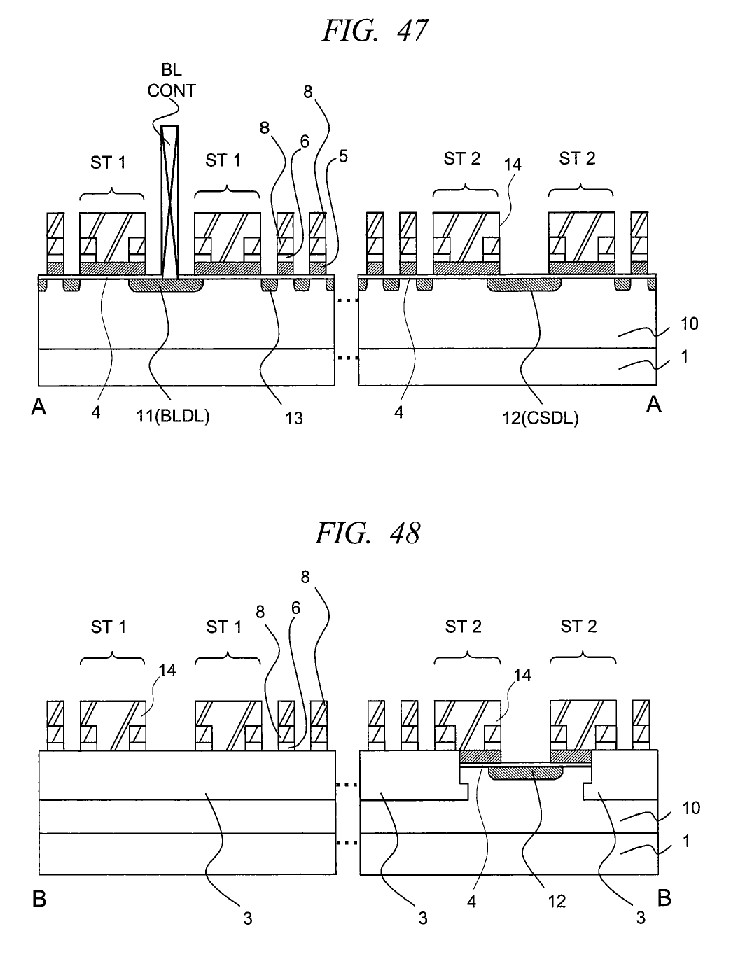

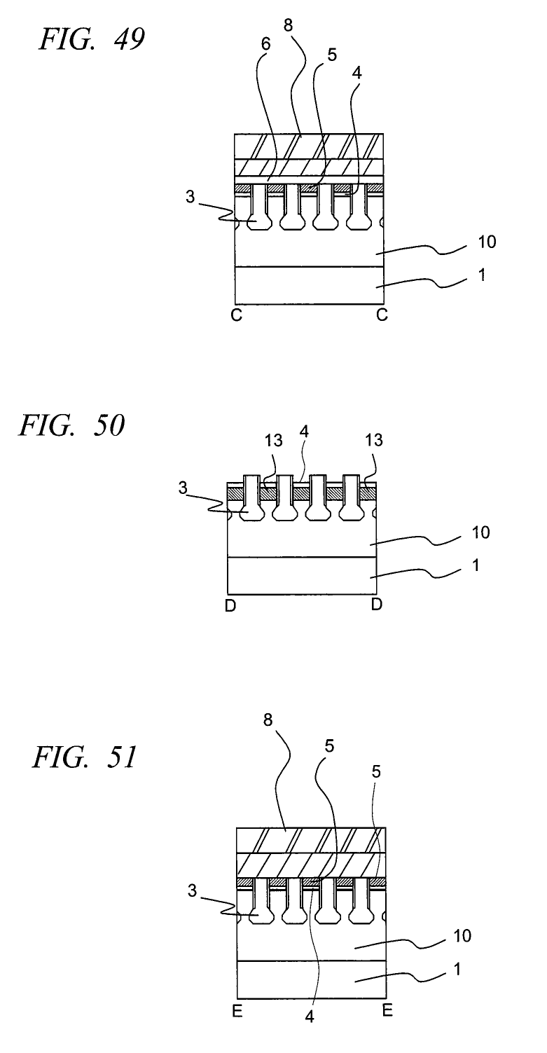

FIG. 47 to FIG. 51 are cross sectional views showing a semiconductor device according to a third embodiment, and they correspond to the cross sectional views taken along A-A line, B-B line, C-C line, D-D line, and E-E line in FIG. 1, respectively.

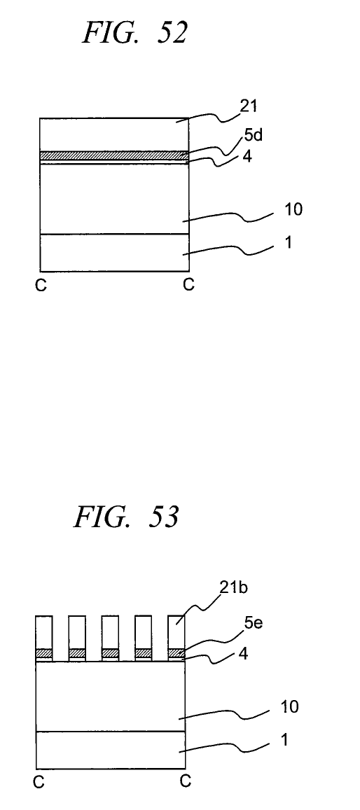

In the first and second embodiments mentioned above, the cross sectional shape of the floating gate 5 is a reversed T shape. Meanwhile, in the present embodiment, the cross sectional shape of the floating gate 5 is designed to be a rectangular shape. The manufacturing method according to the present embodiment will be described below. First, as shown in FIG. 52, after a p type well 10 is formed in a substrate 1, a gate insulator film 4 made of a silicon oxide film is formed on the surface of the p type well 10 by the thermal oxidization method. Then, a phosphorus doped polysilicon film 5d and a silicon nitride film 21 are deposited on the gate insulator film 4 by the CVD method.

Next, as shown in FIG. 53, a silicon nitride film 21a is patterned by the dry etching with using a photoresist film as a mask to form a silicon nitride film 21b. FIG. 16 shows the planar shape of the silicon nitride film 21b. Next, a polysilicon film 5d is patterned by the dry etching with using the silicon nitride film 21b as a mask to form a polysilicon film 5e. Then, the gate insulator film 4 is dry etched to expose a part of the p type well 10.

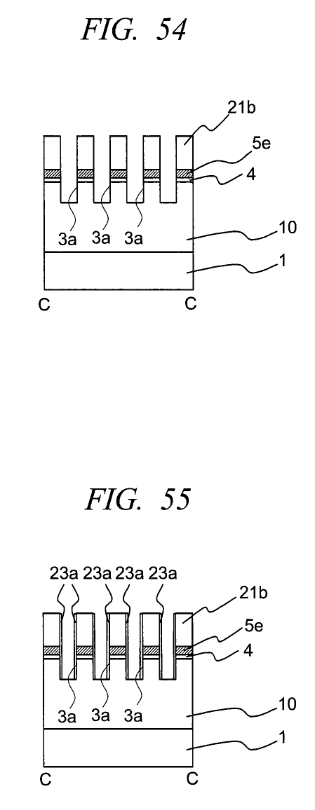

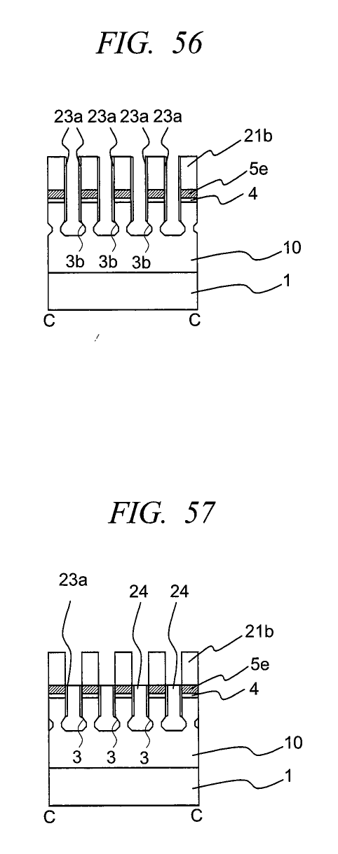

Next, as shown in FIG. 54, the exposed p type well 10 is dry etched, thereby forming a plurality of trenches 3a. Thereafter, as shown in FIG. 55, the silicon oxide film 23 deposited by the CVD method is anisotropically dry etched, thereby exposing the p type well 10 at the bottom of the trenches 3a, and sidewall shaped silicon oxide films 23a are formed on the sidewalls of the silicon nitride film 21b, the polysilicon film 5e, and the trenches 3a, respectively.

Next, as shown in FIG. 56, the p type well 10 exposed at the bottom of the trenches 3a is isotropically etched. By this means, the bottom portions of the trenches 3a are expanded in the vertical direction and the horizontal direction with respect to the main surface of the substrate 1, and the trenches 3b where the diameter at the bottom is larger than the diameter at the vicinity of the opening portion are formed. Next, as shown in FIG. 57, after the silicon oxide 24 is deposited by the use of the CVD method to completely fill the trenches 3b by the silicon oxide 24, the silicon oxides 23a and 24 outside the trenches 3b are etched back, and the silicon oxide film 24 is left only inside the trenches 3b. Through the processes described above, the device isolation trenches 3 where the diameter at the bottom is larger than that at the vicinity of the surface are completed.

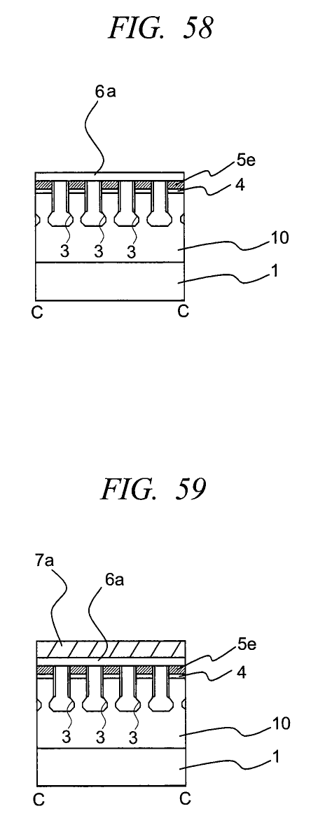

Next, as shown in FIG. 58, after the silicon nitride film 21b is removed by the dry etching or wet etching, an insulator film 6a is deposited. Similar to the first embodiment, the insulator film 6a can be formed of a stacked film of a silicon oxide film/a silicon nitride film/a silicon oxide film deposited by the use of the CVD method or the like, but in the present embodiment, the cross sectional shape of the floating gate 5 is designed to be a rectangular shape, and the capacitance between the control gate and the floating gate is secured only by the upper surface of the floating gate. Accordingly, the sufficient capacitance cannot be expected. Therefore, in order to secure the coupling ratio, the insulator film 6a is formed of a material with a dielectric constant lower than that of the stacked film of a silicon oxide film/a silicon nitride film/a silicon oxide film, for example, Al₂O₃ or HfO₂ or the like.

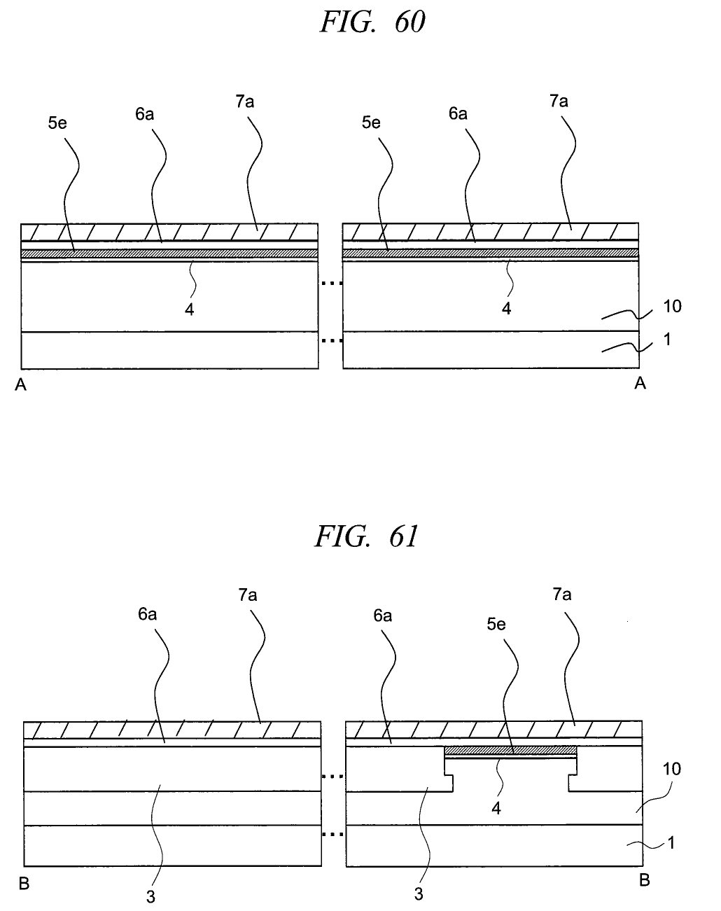

Next, as shown in FIG. 59, a phosphorus doped polysilicon film 7a is deposited. FIG. 60 is a cross sectional view taken along A-A line in FIG. 1 at this time, and FIG. 61 is a cross sectional view taken along B-B line in FIG. 1 at this time. The subsequent processes will be described with reference to the cross sectional view taken along the A-A line and the cross sectional view taken along the B-B line.

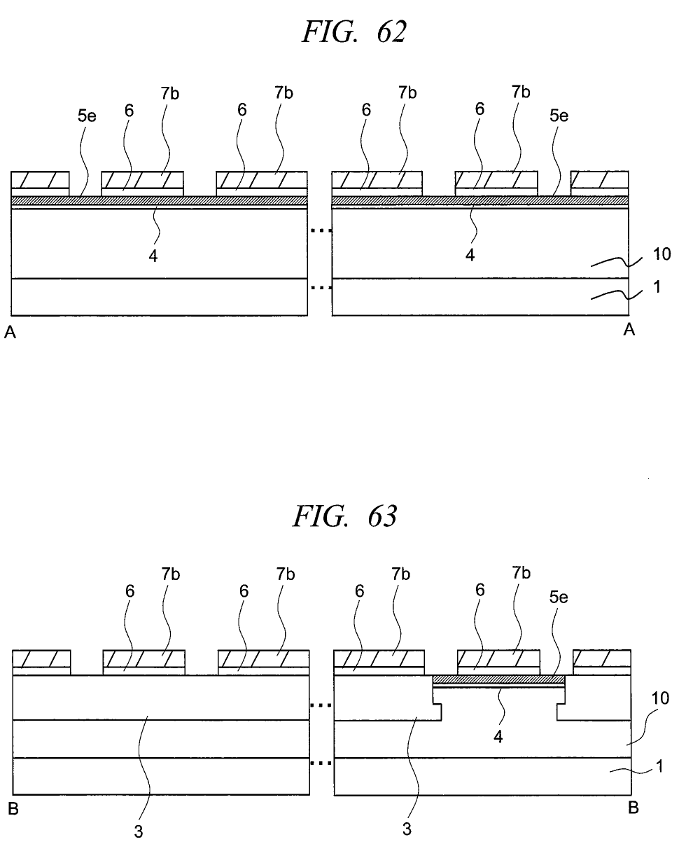

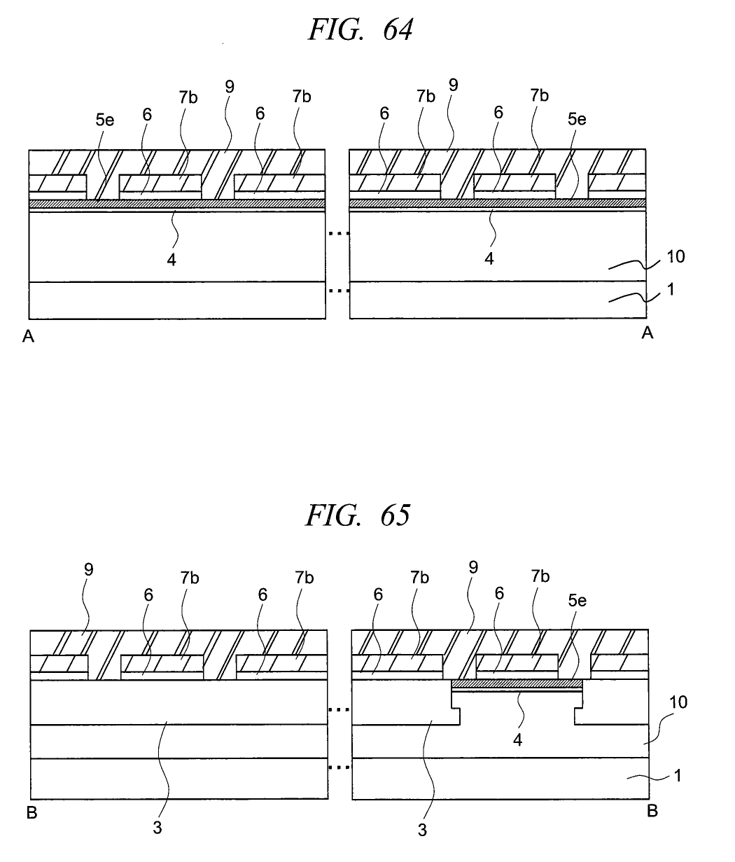

Next, as shown in FIG. 62 and FIG. 63, the polysilicon film 7a and the insulator film 6a in the area where the select transistors (ST₁, ST₂) are to be formed in the latter process are patterned to be a polysilicon film 7b and an insulator film 6, respectively. Next, as shown in FIG. 64 and FIG. 65, a metal film 9 is deposited by the use of the sputtering method. The metal film 9 is formed of, for example, a stacked film of a tungsten nitride film and a tungsten film, a metal silicide film such as a tungsten silicide film and the like.

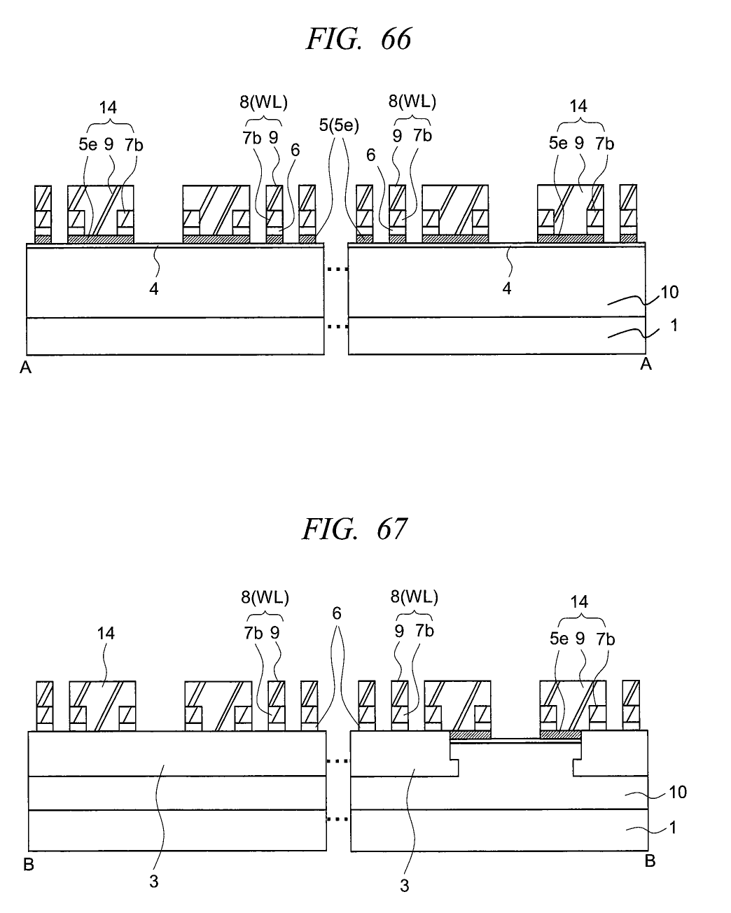

Next, as shown in FIG. 66 and FIG. 67, the metal film 9, the polysilicon film 7b, the insulator film 6 and the polysilicon film 5e are patterned sequentially by the dry etching with using a photoresist film as a mask. Through the processes described above, the control gate 8 (word line WL) made of the stacked film of the metal film 9 and the polysilicon film 7b and the floating gate 5 made of the polysilicon film 5e are formed. Further, at the end of the memory array area, the gate electrodes 14 of the select transistors (ST₁, ST₂) made of the stacked film of the metal film 9 and the polysilicon films 7b and 5e is formed. The subsequent processes are the same as those in the first embodiment.

In the NAND flash memory according to the present embodiment, similar to the first embodiment, it is possible to reduce the memory cell size without reducing the aspect ratio of the device isolation trenches. Accordingly, it is possible to increase the capacity of the NAND flash memory without decreasing the manufacturing yield thereof. Further, an effect that it is possible to reduce the voltage to be applied to the unselected word lines at the time of programming operation can be obtained.

### Fourth Embodiment

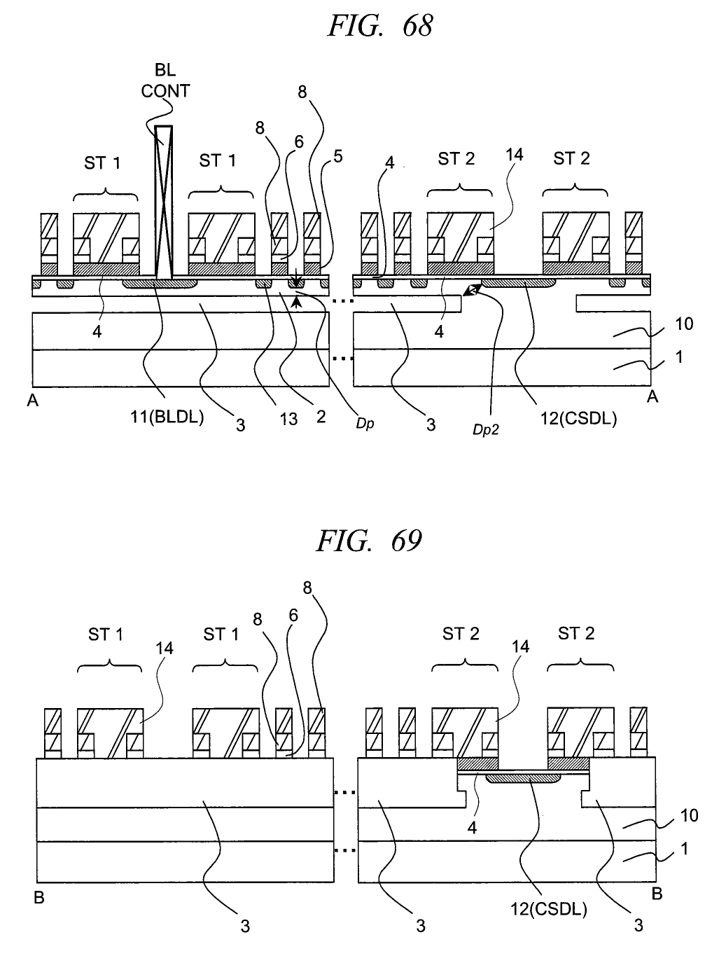

FIG. 68 to FIG. 72 are cross sectional views showing a principal part of a semiconductor device according to a fourth embodiment, and they correspond to the cross sectional views taken along A-A line, B-B line, C-C line, D-D line, and E-E line in FIG. 1, respectively.

In the present embodiment, similar to the second embodiment described above, the bottom portion of the device isolation trench 3 is connected to the bottom portions of the device isolation trenches 3 of adjacent memory cells. Further, similar to the third embodiment described above, the cross sectional shape of the floating gate is rectangular.

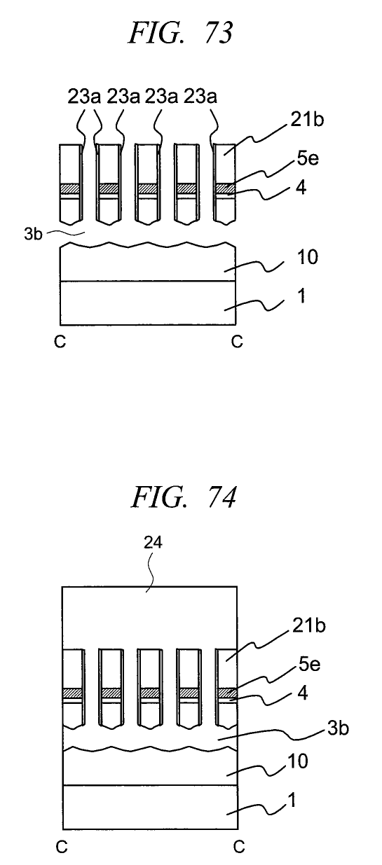

The manufacturing method according to the present embodiment will be described below. First, according to the processes shown in FIG. 52 to FIG. 56 of the third embodiment, trenches 3b where the diameter at the bottom is larger than the diameter at the vicinity of the opening portion are formed. Next, as shown in FIG. 73, the p type well 10 at the bottom of the trenches 3b is isotropically etched to further expand the diameter of the bottom portions of the trenches 3b, and adjacent trenches 3b are connected at the bottoms thereof. Next, as shown in FIG. 74, a silicon oxide film 24 is deposited by the use of the CVD method to completely fill the trenches 3b with the silicon oxide 24. Thereafter, the silicon oxide films 23a and 24 outside the trenches 3b are etched back, and the silicon oxide 24 is left only inside the trenches 3b. The subsequent processes are the same as those in FIG. 57 and thereafter in the third embodiment.

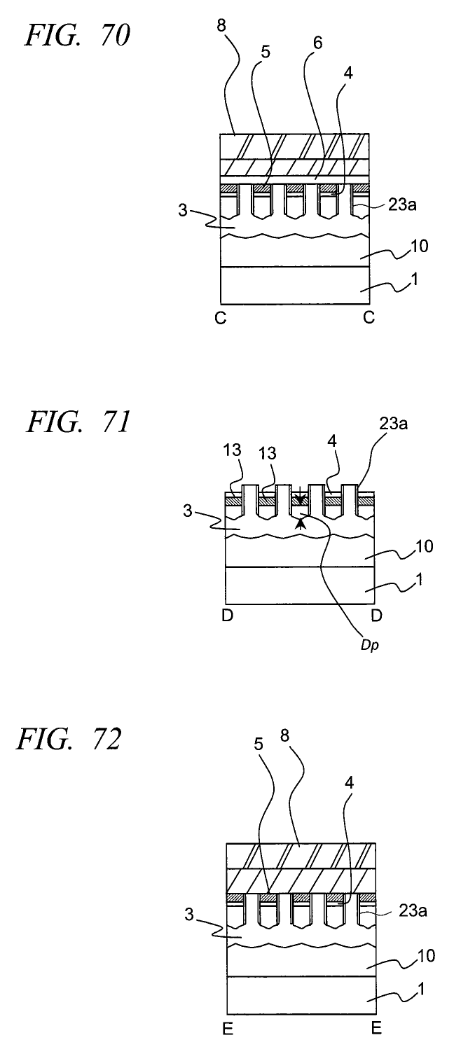

As described in the second embodiment, in the case where the device isolation trenches 3 are designed to have the structure as mentioned above, it is preferable that the n type diffusion layers 13 (source, drain) of the memory cell do not reach the device isolation trenches 3. In other words, it is preferable that the distance (Dp) from the bottom of the diffusion layer 13 to the device isolation trench 3 shown in FIG. 68 and FIG. 71 becomes a positive value (Dp>0). Similarly, it is also preferable that the distance (Dp2) from the end of the n type diffusion layer 12 (common source line) shown in FIG. 68 to the device isolation trench 3 becomes a positive value (Dp2>0).

Further, in the present embodiment, the device isolation characteristics of the device isolation trenches 3 are secured by the insulation of the silicon oxide 24 embedded in the device isolation trenches 3 instead of silicon. Accordingly, it is possible to realize further preferable device isolation characteristics in comparison with the third embodiment.

Further, in the present embodiment, the device isolation trenches 3 in which the silicon oxide film (relative dielectric constant=3.9) whose dielectric constant is lower than that of silicon (specific dielectric constant=11.9) is embedded expand over the entire memory array area. Accordingly, the substrate depletion layer capacitance (Cdep) in the equation (1) is further reduced than that in the first embodiment. Therefore, the coupling ratio [Cox/(Cox+Cdep)] is further increased. As a result, it is possible to generate the substrate surface voltage (VH) for realizing programming prevention with a further lower floating gate voltage change (ΔVfg) and possible to further decrease the voltage to be applied to unselected word lines at the time of programming operation.

### Fifth Embodiment

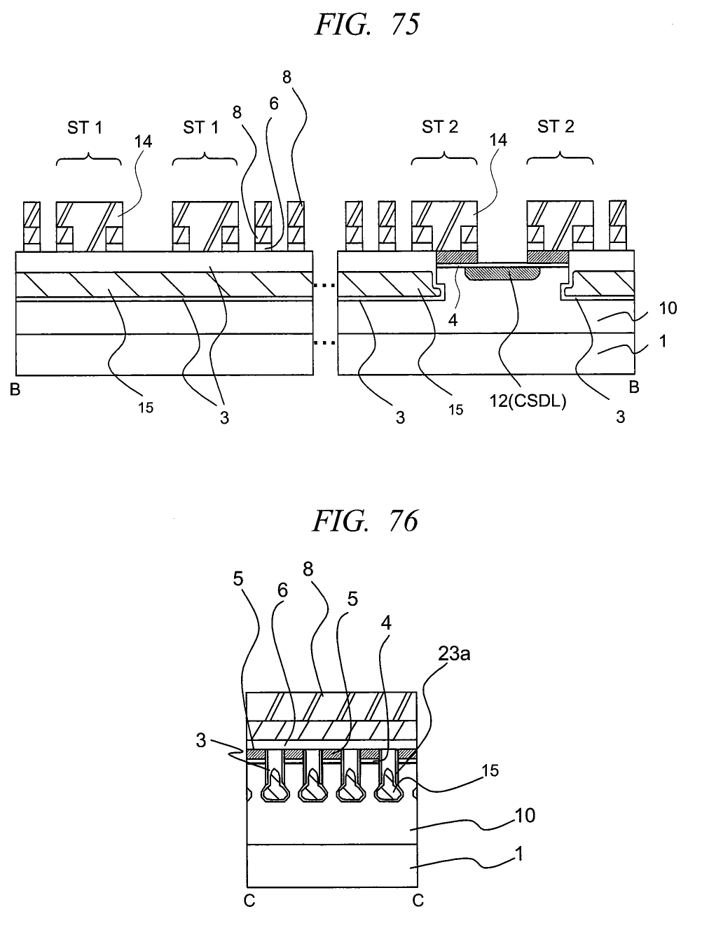

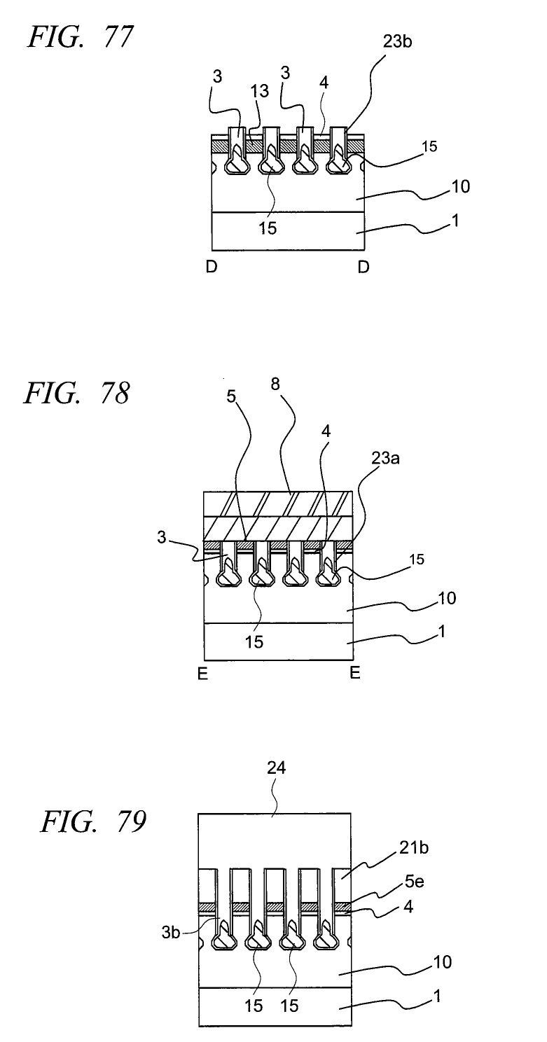

FIG. 75 to FIG. 78 are cross sectional views showing a semiconductor device according to a fifth embodiment, and they correspond to the cross sectional views taken along B-B line, C-C line, D-D line, and E-E line in FIG. 1 respectively. Note that the device isolation trenches are not provided in the cross section taken along the A-A line, and it has the same cross sectional structure as that in FIG. 47 (A-A line cross section) of the third embodiment.

In the first to fourth embodiments mentioned above, the silicon oxide 24 is embedded in the device isolation trenches 3. In the present embodiment, however, a cavity 15 is provided in the device isolation trench 3. In order to form the cavities 15, first, deposition conditions of bad covering properties are used when the silicon oxide 24 is embedded in the trenches 3a in the process shown in FIG. 57 of the third embodiment. In this manner, as shown in FIG. 79, the bottom portions of the trenches 3b whose diameter is wider than that of the opening portion are not completely filled with the silicon oxide film 24, and the cavities 15 are formed. The subsequent processes are the same as those in FIG. 57 and thereafter in the third embodiment.

In the present embodiment, since the cavities 15 (specific dielectric constant nearly 1.0) of the silicon oxide 24 are provided in the device isolation trenches 3, inversion of the surface of the device isolation trench 3 due to the word line voltage hardly occurs, and it is possible to realize a further preferable device isolation characteristics in comparison with the third embodiment mentioned above.

Further, since there are the cavities 15 whose dielectric constant is lower than that of the silicon oxide film (relative dielectric constant 3.9) in the device isolation trenches 3, the substrate depletion layer capacitance (Cdep) in the equation (1) is further reduced than in the third embodiment, and consequently, the coupling ratio [Cox/(Cox+Cdep)] is further increased. Therefore, it is possible to generate the substrate surface voltage (VH) for realizing programming prevention with a further lower floating gate voltage change (ΔVfg), and also possible to reduce the voltage to be applied to unselected word lines at the time of programming operation.

### Sixth Embodiment

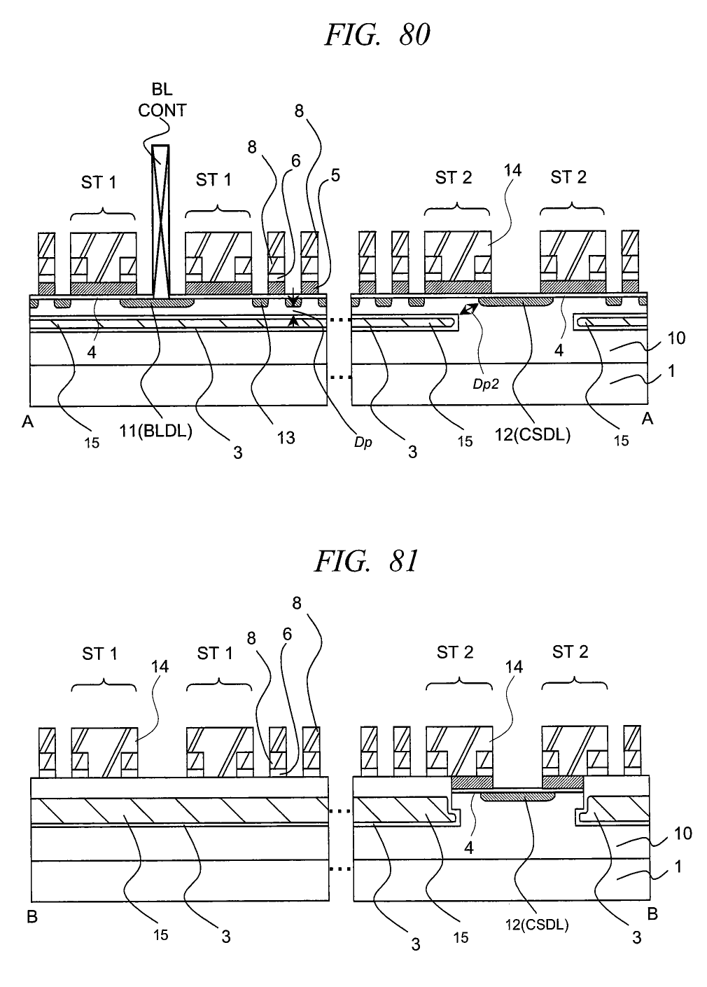

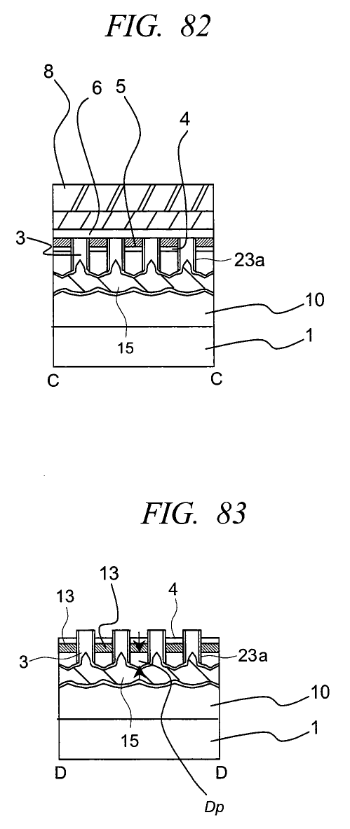

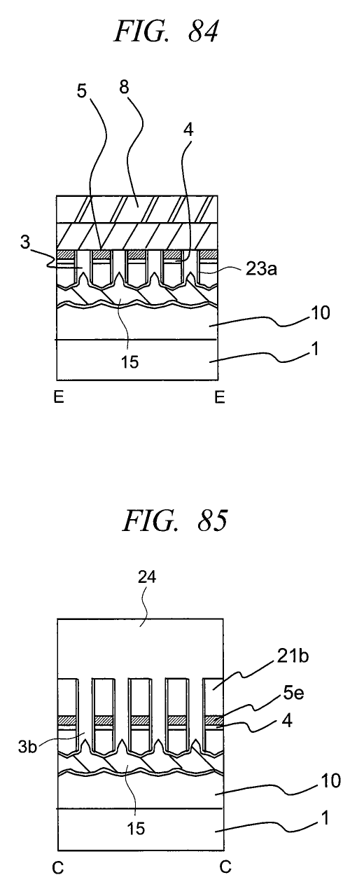

FIG. 80 to FIG. 84 are cross sectional views showing a semiconductor device according to a sixth embodiment, and they correspond to the cross sectional views taken along A-A line, B-B line, C-C line, D-D line, and E-E line in FIG. 1, respectively.

In the present embodiment, similar to the second and fourth embodiments mentioned above, the bottom portion of the device isolation trench 3 is connected to the bottom portions of the device isolation trenches 3 of adjacent memory cells. Further, similar to the fifth embodiment, the cavities 15 are provided in the device isolation trenches 3. In order to form the cavities 15, first, deposition conditions of bad covering properties are used when the silicon oxide 24 is embedded in the trenches 3a in the process shown in FIG. 74 of the fourth embodiment. In this manner, as shown in FIG. 85, the bottom portions of the trenches 3b whose diameter is wider than that of the opening portion are not completely filled with the silicon oxide film 24, and the cavities 15 are formed. The subsequent processes are the same as those in FIG. 57 and thereafter in the third embodiment.

As described in the second embodiment, in the case where the device isolation trenches 3 are designed to have the structure as mentioned above, it is preferable that the n type diffusion layers 13 (source, drain) of the memory cell do not reach the device isolation trenches 3. In other words, it is preferable that the distance (Dp) from the bottom of the diffusion layer 13 to the device isolation trench 3 shown in FIG. 80 and FIG. 83 becomes a positive value (Dp>0). Similarly, it is also preferable that the distance (Dp2) from the end of the n type diffusion layer 12 (common source line) shown in FIG. 80 to the device isolation trench 3 becomes a positive value (Dp2>0).

Further, in the present embodiment, the device isolation characteristics of the device isolation trenches 3 are secured by the insulation of the silicon oxide 24 embedded in the device isolation trenches 3 instead of silicon. Accordingly, it is possible to realize further preferable device isolation characteristics in comparison with the third embodiment.

Furthermore, in the present embodiment, similar to the fourth embodiment, the device isolation characteristics of the device isolation trenches 3 are secured by the insulation of the silicon oxide 24 embedded in the device isolation trenches 3 instead of silicon. Accordingly, it is possible to realize further preferable device isolation characteristics in comparison with the fifth embodiment.

Further, in the present embodiment, the device isolation trenches 3 in which the silicon oxide film (relative dielectric constant=3.9) whose dielectric constant is lower than that of silicon (specific dielectric constant=11.9) is embedded expand over the entire memory array area. Accordingly, the substrate depletion layer capacitance (Cdep) in the equation (1) is further reduced than that in the first embodiment. Therefore, the coupling ratio [Cox/(Cox+Cdep)] is further increased. As a result, it is possible to generate the substrate surface voltage (VH) for realizing programming prevention with a further lower floating gate voltage change (ΔVfg) and possible to further decrease the voltage to be applied to unselected word lines at the time of programming operation.

### Seventh Embodiment

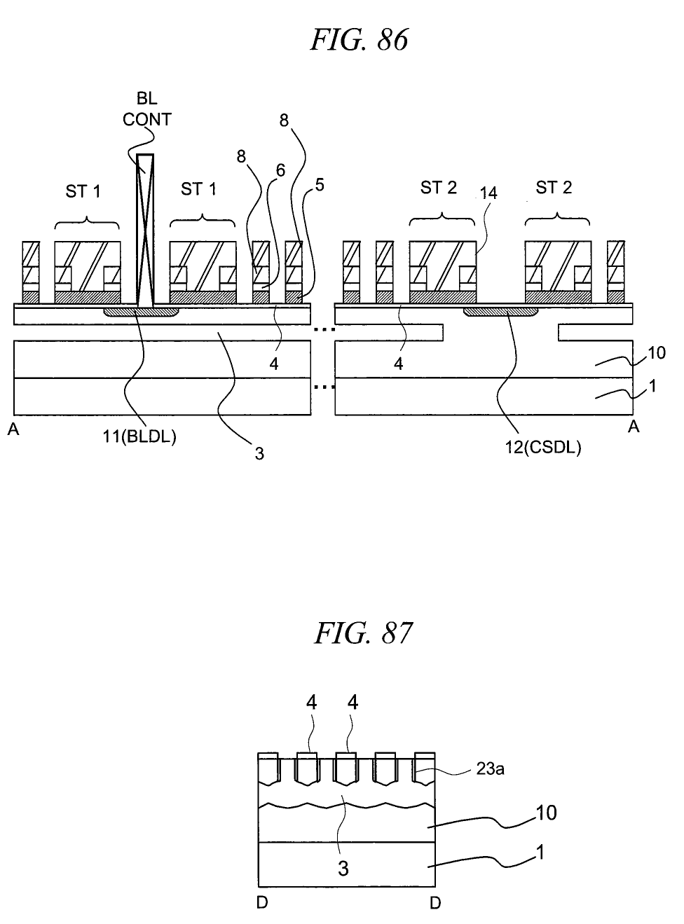

FIG. 86 and FIG. 87 are cross sectional views showing a semiconductor device according to a seventh embodiment, and they correspond to the cross sectional views taken along A-A line and D-D line in FIG. 1, respectively. Note that the cross sectional views taken along B-B line, C-C line, and E-E line are the same as those in the sixth embodiment.

In the first to sixth embodiments, impurity (arsenic) is ion implanted into the p type well 10, thereby forming the n type diffusion layers 13 (source, drain) of the memory cell. In the present embodiment, however, the n type diffusion layers 13 (source, drain) are not formed by the impurity ion implantation.

The n type diffusion layer 13 is formed in order to connect a plurality of memory cells arranged in the column direction in series. However, when the distance between memory cells becomes about 30 nm or less due to the reduction of memory cell size, since inversion layers of a plurality of memory cells arranged in the column direction are connected together, the formation of the n type diffusion layer 13 can be omitted.

Also in the present embodiment, the diameter of the bottom portions of the device isolation trenches 3 is made larger than the diameter at the vicinity of the surface. In this case, similar to the second and fourth embodiments, the bottom portion of the device isolation trench 3 can be connected to the bottom portions of other device isolation trenches 3 of adjacent memory cells. Further, similar to the fifth and sixth embodiments, the cavities 15 can be provided in the device isolation trenches 3.

In the case where the bottom portion of the device isolation trench 3 is connected to the bottom portions of other device isolation trenches 3 of adjacent memory cells, if the diffusion layer 13 is not formed, it is not necessary to form the diffusion layer so that the distance Dp between the bottom portion of the diffusion layer and the bottom portion of the silicon wire becomes a positive value, which must be considered in the cases of the second, fourth, and sixth embodiments. In the case where the diffusion layer 13 is formed, since the thickness of the silicon wire is also reduced together with the reduction of memory cell size, the diffusion layer 13 must be formed to be thin in order to secure the distance Dp. However, this is extremely difficult. When the memory cell is further miniaturized, the distance between word lines is accordingly reduced. Therefore, only by applying positive voltage to the adjacent word lines at the time of reading/programming operation, the silicon substrate surface of the space portion between the word lines also becomes an inverted state. Accordingly, even without forming the diffusion layer 13, it is possible to realize the normal operation of the NAND flash.

On the other hand, with regard to the distance Dp2, it is important that it should be a positive value. Similar to the second and fourth embodiments, by forming the gate of ST2 so as to be over the bulk silicon area and the silicon wire area, the memory cell can be formed on the silicon wire, and Dp2>0 can be achieved.

### Eighth Embodiment

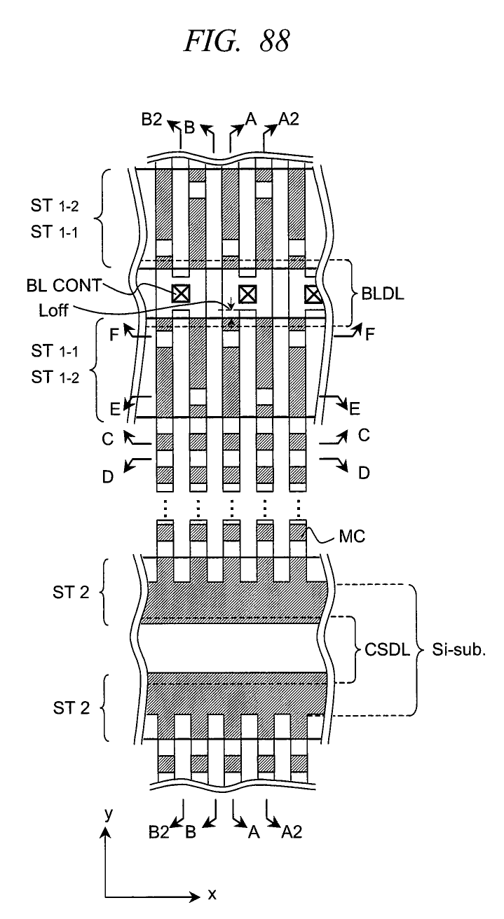

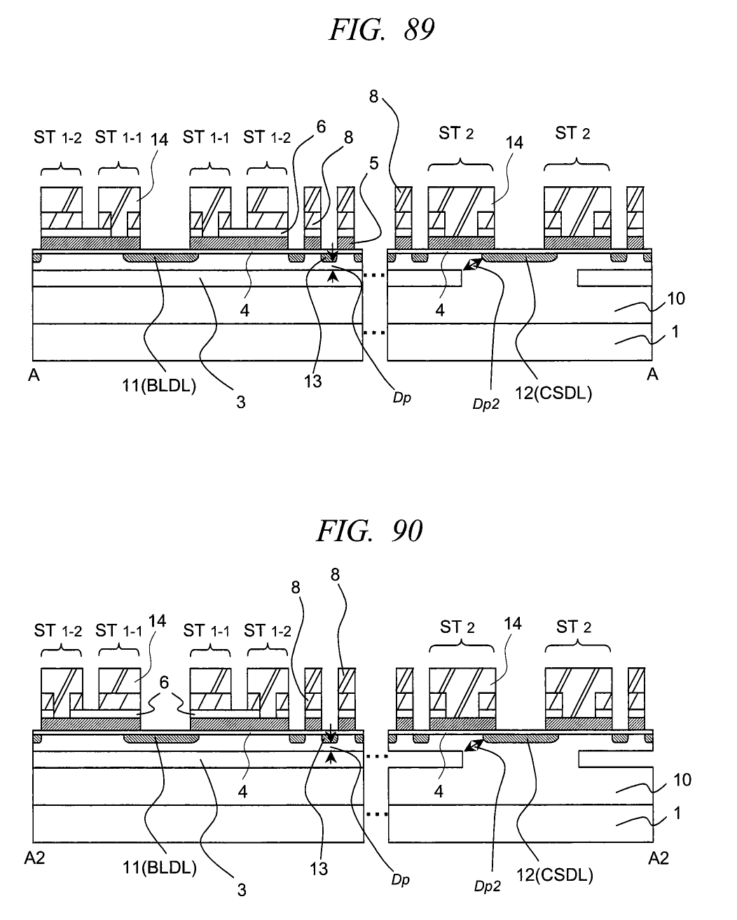

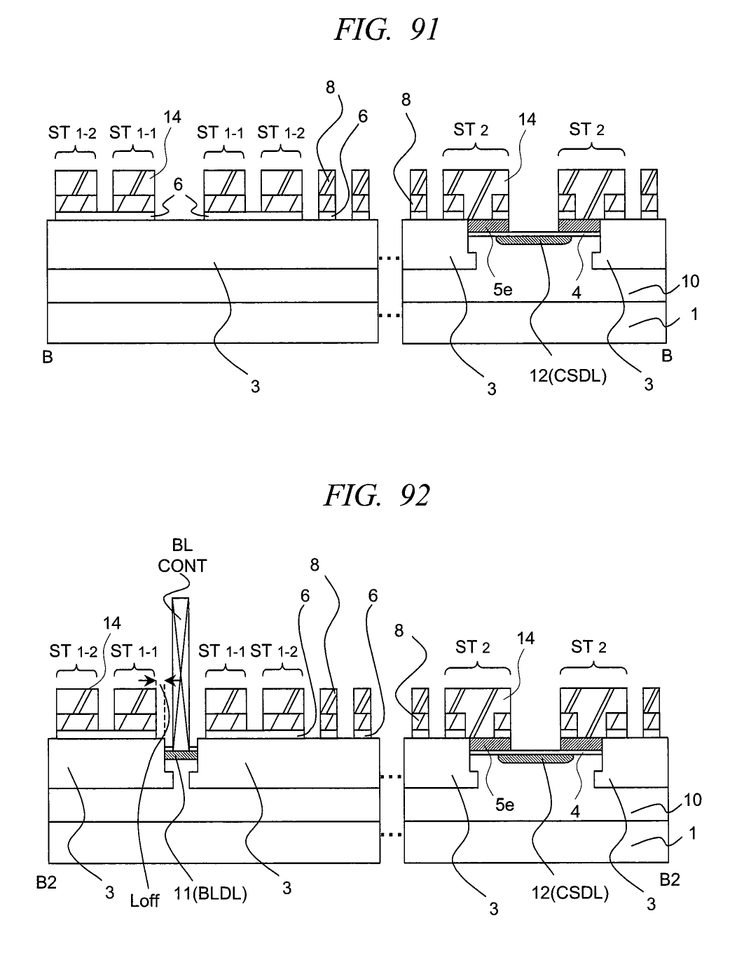

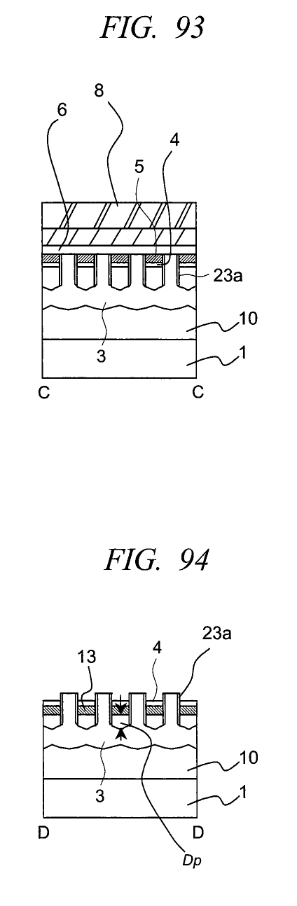

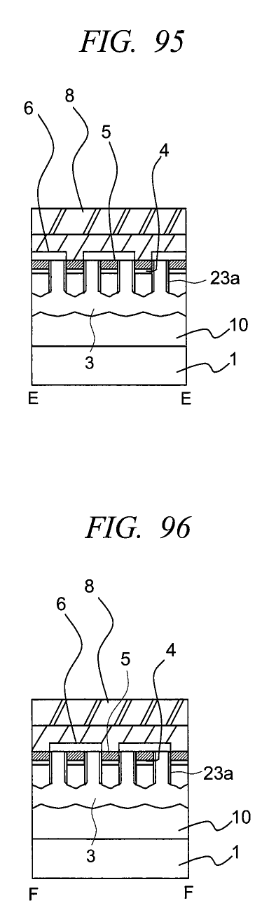

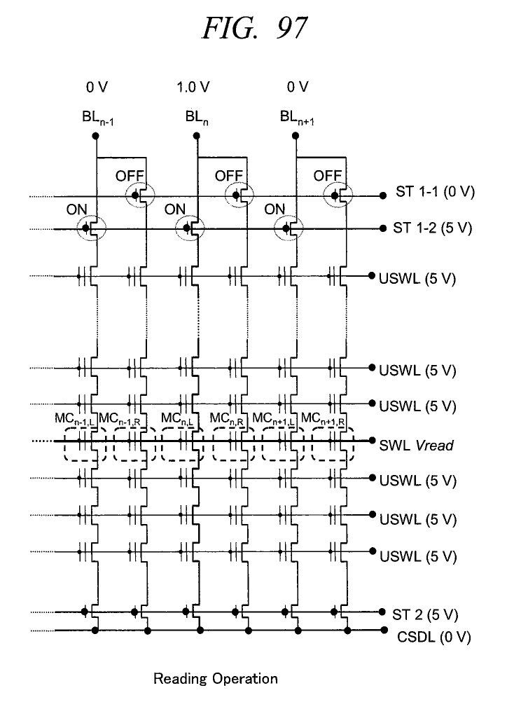

FIG. 88 is a plan view showing the memory array area of a semiconductor device according to an eighth embodiment, and FIG. 89 to FIG. 96 are cross sectional views taken along A-A line, A2-A2 line, B-B line, B2-B2 line, C-C line, D-D line, E-E line, and F-F line in FIG. 88, respectively. Note that, in FIG. 88, some of components are omitted for easy recognition of the structure of the memory array area.

In the first to seventh embodiments mentioned above, one bit line contact (BLCONT) is disposed for each of the memory cell column extending in the column direction. Meanwhile, in the present embodiment, one bit line contact (BLCONT) is disposed for each two memory cell columns. In other words, one bit line (BL) made of metal wire is connected to two memory cell columns (FIG. 97 to FIG. 99). Such a bit line layout is effective in the case where the pitch of bit lines (BL) becomes narrow due to the reduction of memory cell size and it becomes difficult to dispose one bit line contact (BLCONT) for each memory cell column or to dispose one bit line (BL) for each memory cell column.

The memory cell column extending in the column direction is connected to two select transistor ST₁₋₁ and select transistor ST₁₋₂ at one end of the memory array area and is connected via these two select transistors (ST₁₋₁, ST₁₋₂) to the n type diffusion layer 11 (BLDL), the bit line contact (BLCONT) and the bit line (BL). Further, one memory cell column adjacent to the memory cell column mentioned above is also connected via the two select transistors (ST₁₋₁, ST₁₋₂) to the n type diffusion layer 11 (BLDL), the bit line contact (BLCONT) and the bit line (BL).

Whether either of the two adjacent memory cell columns is connected to the n type diffusion layer 11 (BLDL) is controlled by ON and OFF of the select transistors (ST₁₋₁, ST₁₋₂). For its achievement, the length shown by Loff in FIG. 88 and FIG. 92 from the end of the gate electrode 14 of the select transistor ST₁₋₁ to the end of the device isolation trench 3 in contact with the n type diffusion layer 11 (BLDL) is set to Loff>0. More specifically, the channel of the select transistor ST₁₋₁, connected to one of the two memory cell columns connected to the common n type diffusion layer 11 (BLDL) and the channel of the select transistor ST₁₋₁ connected to the other thereof are mutually separated from each other by the device isolation trench 3.

Further, similar to the gate electrode 14 of the select transistor (ST₁) of the first to seventh embodiments mentioned above, the gate electrode 14 of the select transistors (ST₁₋₁, ST₁₋₂) has a stacked structure of a floating gate material (polysilicon film 5e) and control gate (word line) materials (metal film 9 and polysilicon film 7b). However, as shown in the cross sectional view, the floating gate material (polysilicon film 5e) of the select transistor ST₁₋₁ and the floating gate material (polysilicon film 5e) of the select transistor ST₁₋₂ are mutually insulated from each other and are connected to respectively different control gate materials (metal film 9 and polysilicon film 7b), and can separately supply power.

The device isolation trenches 3 according to the present embodiment are formed by the same method as those of the second and fourth embodiments mentioned above, and as shown in FIG. 92, the p type well 10 in the area where the n type diffusion layer 11 (BLDL) is formed is connected to the substrate 1 at the position under the n type diffusion layer 11 (BLDL).

Next, the operation of the NAND flash memory according to the present embodiment will be described below. For example, at the time of reading the memory cells (MC_{n, L}) shown in FIG. 97, 1V is applied to the bit line (BLₙ) connected to the memory cells (MC_{n, L}) and 0V is applied to other bit lines, respectively. Also, 0V is applied to the select transistor ST₁₋₁, about 5V is applied to the select transistor ST₁₋₂, about 5V is applied to the unselected word line (USWL), 0V is applied to the common source line (CSDL), and 0V is applied to the p type well 10, respectively. Further, read verify voltage (Vread) is applied to the selected word line (SWL) to determine ON or OFF of the memory cell (MC_{n, L}).

Programming is performed by the use of the Fowler-Nordheim tunnel current via a tunnel insulator film 4 to a plurality of memory cells connected to the selected word line (SWL). In this case, the distinction between the memory cells to which programming is to be performed and the memory cells to which programming is not to be performed among the plurality of memory cells connected to the selected word line (SWL) is controlled by the size of the voltage to be applied to the bit line (BL).

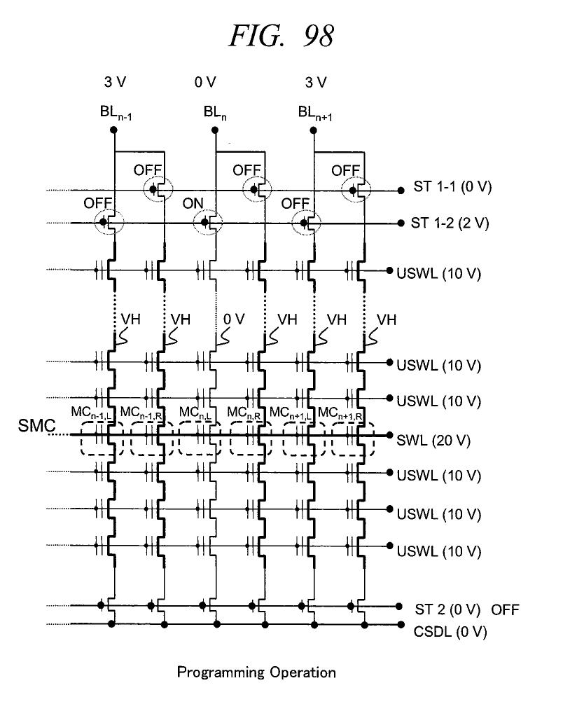

More specifically, at the time of programming to the memory cell (MC_{n, L}) shown in FIG. 98, 0V is applied to the bit line (BLₙ) connected to the memory cell (MC_{n, L}) and about 3V is applied to other bit lines. Also, 0V is applied to the select transistor ST₁₋₁, about 2V is applied to the select transistor ST₁₋₂, 0V is applied to the common source line (CSDL), and 0V is applied to the select transistor ST₂ and the p type well 10, respectively. In this state, the voltage of the unselected word line (USWL) is increased from 0V to about 10V rapidly (about several micro seconds or less). Then, the voltage of the floating gate 5 under the unselected word line (USWL) increases and the voltage of substrate surface under the memory cell will increase due to the influence thereof. In the case where 3V is applied to the bit line, since the select transistor ST₁₋₁ is in an OFF state, the voltage of substrate surface under the memory cell increases and becomes VH. On the other hand, in the bit line whose bit line voltage is set to 0V, since the select transistor ST₁₋₁ is in an ON state, electrons are supplied from the bit line contact side to the substrate surface under the memory cell, and the voltage becomes 0V.

Next, the voltage of the selected word line (SWL) is increased from 0V to about 20V. At this time, in the bit line whose bit line voltage is 0V, a large voltage difference occurs between the floating gate and the substrate surface, electrons are injected from the substrate surface to the floating gate by tunnel current and the programming is performed. On the other hand, in the bit line where the voltage of the substrate surface is VH, the difference in voltages between the floating gate and the substrate surface is reduced, and the programming is not performed.

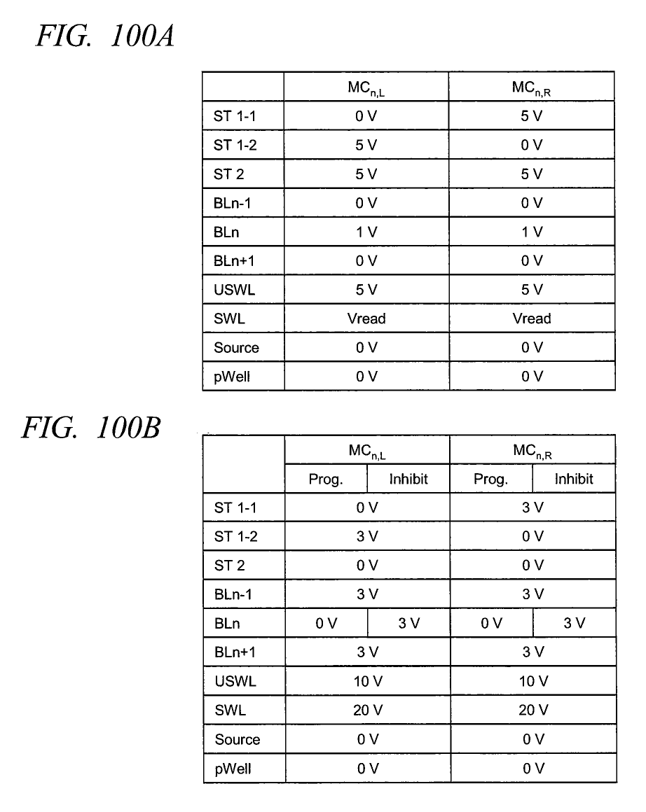

The voltage conditions of reading and programming of the memory cells (MC_{n, L}) and the memory cells (MC_{n, R}) connected to the same bit line contact and selected word line are shown in FIG. 100. The reading voltage condition is shown in FIG. 100A and the programming condition is shown in FIG. 100B. In FIG. 100B, Prog. shows the case where programming is performed into the memory cell and Inhibit shows the case where programming is not performed. With regard to the programming, in the case where the programming is performed to the memory cells (MC_{n, L}), the memory cells (MC_{n, R}) are automatically in the state where the programming is not performed. In other words, when the select transistor ST₁₋₁ is OFF, the substrate surface under the memory cell (MC_{n, R}) becomes VH irrespective of the voltage of BLn, and when the select transistor ST₁₋₂ is OFF, the substrate surface under the memory cell (MC_{n, L}) becomes VH irrespective of the voltage of BLn, and programming is not performed respectively.

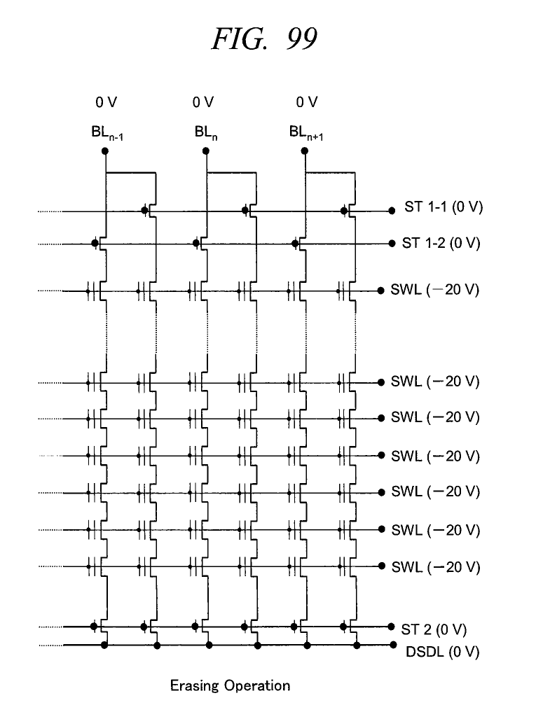

At the time of erasing operation, as shown in FIG. 99, about −20V is applied to all the word lines between the select transistors (ST₁₋₁, ST₁₋₂) and the select transistor ST₂, and electrons are ejected from the floating gate to the substrate via the gate insulator film by the Fowler-Nordheim tunnel current.

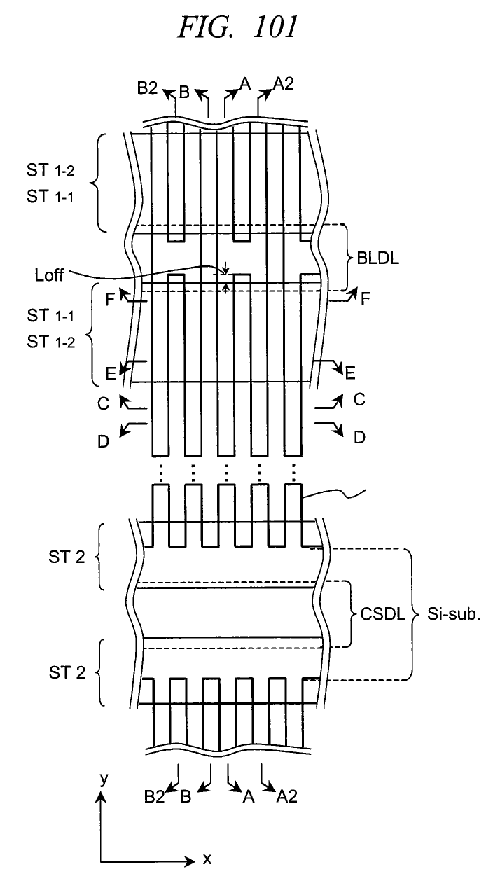

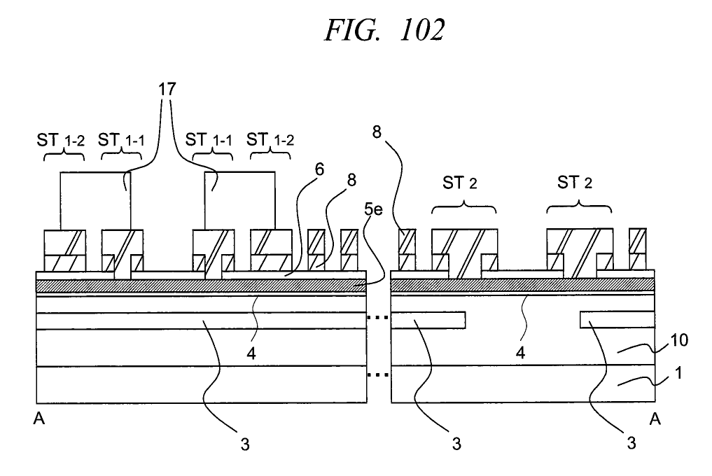

The semiconductor device according to the present embodiment can be manufactured by the same method as that in the fourth embodiment. However, in the course, the silicon nitride film 21a is formed to have such a planar shape as shown in FIG. 101. Further, when processing the word lines, attention must be paid so that the polysilicon film 5b is not separated at the border portion of the select transistor ST₁₋₁ and the select transistor ST₁₋₂. After the control gate layers 8a and 7b of the word line are patterned, as shown in FIG. 102, a resist pattern 17 is formed at the border portion of the select transistor ST₁₋₁ and the select transistor ST₁₋₂. Thereafter, the insulator film 6 and the polysilicon film 5a are processed with using the control gate and the resist pattern 17 as masks. FIG. 102 shows the cross section taken along the A-A line, and the cross sections at the border portion of the select transistor ST₁₋₁ and the select transistor ST₁₋₂ taken along the A2-A2 line, the B-B line, and the B2-B2 line are equal to that taken along the A-A line.

Similar to the second and fourth embodiments, it is important that the dimension Dp in FIG. 89, FIG. 90, and FIG. 94 becomes a positive value when forming the diffusion layers 13 (source, drain) of the memory cell. Electrons discharged from the floating gate to the silicon substrate surface at the time of erasing operation have to be discharged through the p type well 10 to the bulk silicon (substrate 1). If Dp becomes 0, electrons discharged at the time erasing operation are accumulated in the p type well 10, and the difference in voltages between the floating gate and the surface of the p type well 10 becomes small. Consequently, the erasing speed becomes very slow.

From the same reason, it is important that the distance Dp2 shown in FIG. 89 and FIG. 90 becomes a positive value. It is possible to achieve Dp2>0 when the gate of the select transistor ST₂ is formed over the bulk silicon area (substrate 1) and the p type well 10.

In the present embodiment, the device isolation characteristics are secured by the insulation of the silicon oxide film (24) embedded in the device isolation trenches 3 instead of silicon. Accordingly, it is possible to realize further preferable device isolation characteristics in comparison with the first embodiment.

Further, in the present embodiment, the device isolation trenches 3 in which the silicon oxide film (relative dielectric constant=3.9) whose dielectric constant is lower than that of silicon (specific dielectric constant=11.9) is embedded expand over the entire memory array area. Accordingly, the substrate depletion layer capacitance (Cdep) in the equation (1) is further reduced than that in the first embodiment. Therefore, the coupling ratio [Cox/(Cox+Cdep)] is further increased. As a result, it is possible to generate the substrate surface voltage (VH) for realizing programming prevention with a further lower floating gate voltage change (ΔVfg) and possible to further decrease the voltage to be applied to unselected word lines at the time of programming operation.

In the foregoing, the invention made by the inventors of the present invention has been concretely described based on the embodiments. However, it is needless to say that the present invention is not limited to the foregoing embodiments and various modifications and alterations can be made within the scope of the present invention.

The present invention is applied to a flash memory to be used in memory devices for personal digital assistants such as a mobile personal computer, a digital still camera, and so forth.

What is claimed is:

1. A semiconductor device comprising:
a plurality of memory cells arranged in a matrix in a first direction and a second direction perpendicular thereto on a main surface of a semiconductor substrate of a first conductive type,
wherein each of the plurality of memory cells is provided with a floating gate formed on the main surface of the semiconductor substrate via a gate insulator film and a control gate formed on the floating gate via an insulator film,
the respective control gates of the plurality of memory cells arranged in the first direction form word lines extending in the first direction in a unified manner,
the plurality of memory cells arranged in the second direction are connected in series,
the memory cells adjacent in the first direction are mutually isolated by device isolation trenches formed in the main surface of the semiconductor substrate and extending in the second direction, and
a diameter of the device isolation trench in the first direction at the bottom portion thereof is larger than a diameter thereof in the first direction at the surface of the semiconductor substrate.

2. The semiconductor device according to claim 1,
wherein a cavity is provided in a part of an insulator film embedded in the device isolation trench.

3. The semiconductor device according to claim 1,
wherein the device isolation trenches adjacent in the first direction are mutually connected at the bottoms thereof.

4. The semiconductor device according to claim 3,
wherein a cavity is provided in a part of an insulator film embedded in the device isolation trench.

5. The semiconductor device according to claim 1,
wherein an end of a memory cell array arranged in the second direction is connected to a diffusion layer of a second conductive type via a select transistor.

6. The semiconductor device according to claim 1,
wherein a cross sectional shape of the floating gate is a reversed T shape.

7. The semiconductor device according to claim 5,
wherein voltage can be supplied independently to gates of the select transistors adjacent in the first direction, and the diffusion layer of a second conductive type is shared by each two select transistors adjacent in the first direction.

8. A manufacturing method of a semiconductor device, comprising:
(a) a step of forming a well of a first conductive type in a semiconductor substrate;
(b) a step of forming a first insulator film on the semiconductor substrate;
(c) a step of forming a plurality of first gates extending in a first direction parallel to the semiconductor substrate and arranged at regular intervals in a second direction perpendicular to the first direction on the first insulator film formed on the well;
(d) a step of forming device isolation trenches in the semiconductor substrate between the first gates adjacent in the first direction so as to extend in the second direction;
(e) a step of embedding the device isolation trenches with an insulator film; and
(f) a step of forming second gates extending in the first direction via the first gates and a second insulator film,
wherein the step (d) of forming the device isolation trenches includes a step of maximizing the dimension of the device isolation trenches in the first direction at a level deeper than a surface of the semiconductor substrate.

9. The manufacturing method of a semiconductor device according to claim 8, further comprising:
when forming the device isolation trenches in the semiconductor substrate,
(g) a step of forming device isolation trenches with a first depth;
(h) a step of forming an insulator film on the surface of the semiconductor substrate in the trenches with the first depth;
(i) a step of anisotropically etching the insulator film and removing only the insulator film at the bottom of the trenches with the first depth; and
(j) a step of isotropically etching the semiconductor substrate to expand the trenches in both of the perpendicular direction and the parallel direction to the surface of the semiconductor substrate.

10. The manufacturing method of a semiconductor device according to claim 8, further comprising: when embedding the device isolation trenches with the insulator film, a step of forming a cavity in the insulator film.

11. The manufacturing method of a semiconductor device according to claim 8, further comprising: when forming the device isolation trenches, a step of mutually connecting the device isolation trenches adjacent in the first direction in the semiconductor substrate.

12. The manufacturing method of a semiconductor device according to claim 11, further comprising: when embedding the device isolation trenches with the insulator film, a step of forming a cavity in the insulator film.

13. The manufacturing method of a semiconductor device according to claim 11, further comprising:
when forming the device isolation trenches in the semiconductor substrate,
(k) a step of depositing a first gate material extending in the second direction via the first insulator film on the well formed on the semiconductor substrate;
(l) a step of depositing a dummy insulator film on the first gate material and a step of forming the first gate and the dummy insulator film into a line/space pattern expanding in the second direction to expose a part of the first insulator film;
(m) a step of removing the exposed part of the first insulator film with using the line/space pattern of the first gate and the dummy insulator film formed in the step (l) as a mask, thereby exposing a part of the semiconductor substrate;
(n) a step of etching the exposed semiconductor substrate to a first depth with using the line/space pattern of the first gate and the dummy insulator film formed in the step (l) as a mask;
(o) a step of forming a silicon oxide film on the surface of the semiconductor substrate in the trenches with the first depth and on the exposed sidewall of the first gate;
(p) a step of anisotropically etching the silicon oxide film to remove only the silicon oxide film at the bottom of the trenches with the first depth; and
(q) a step of isotropically etching the semiconductor substrate after the step (p) to expand the trenches in both of the perpendicular direction and the parallel direction to the surface of the semiconductor substrate.

14. The manufacturing method of a semiconductor device according to claim 13,
wherein, in the step (q), the trenches are expanded until the device isolation trenches adjacent in the first direction are mutually connected.
